(19) United States
(12) Patent Application Publication
(10) Pub. No.: US 2025/0183876 A1
(43) Pub. Date: Jun. 5, 2025

(54) ACOUSTIC WAVE DEVICE

(71) Applicant: Murata Manufacturing Co., Ltd., Nagaokakyo-shi (JP)

(72) Inventors: Sho NAGATOMO, Nagaokakyo-shi (JP); Katsuya DAIMON, Nagaokakyo-shi (JP)

(21) Appl. No.: 19/049,107

(22) Filed: Feb. 10, 2025

Related U.S. Application Data
(63) Continuation of application No. PCT/JP2023/030460, filed on Aug. 24, 2023.
(60) Provisional application No. 63/400,916, filed on Aug. 25, 2022.

(51) Int. Cl. H03H 9/56; H03H 9/02; H03H 9/13; H03H 9/17

(52) U.S. Cl. CPC H03H 9/568; H03H 9/02031; H03H 9/02157; H03H 9/02228; H03H 9/132; H03H 9/173; H03H 9/175; H03H 9/176; H03H 9/562; H03H 9/564

(57) ABSTRACT

An acoustic wave device includes acoustic elements sharing a support, and a piezoelectric film on the support and including a piezoelectric layer that includes a piezoelectric body. The acoustic elements include a first acoustic element that is an acoustic coupling filter, and a second acoustic element electrically connected to the first acoustic element. In plan view, an acoustic reflection portion is provided in the support overlapping with first electrode fingers, second electrode fingers, and third electrode fingers of the first acoustic element and a functional electrode of the second acoustic element.

### CROSS REFERENCE TO RELATED APPLICATIONS

This application claims the benefit of priority to Provisional Application No. 63/400,916 filed on Aug. 25, 2022 and is a Continuation Application of PCT Application No. PCT/JP2023/030460 filed on Aug. 24, 2023. The entire contents of each application are hereby incorporated herein by reference.

### BACKGROUND OF THE INVENTION

### 1. Field of the Invention

The present invention relates to acoustic wave devices each including a plurality of acoustic elements.

### 2. Description of the Related Art

In the related art, an acoustic wave device is widely used as a filter or the like of a mobile phone. In recent years, as described in U.S. Pat. No. 10,491,192, an acoustic wave device using a bulk wave in a thickness shear mode has been proposed. In the acoustic wave device, a piezoelectric layer is provided on a support body. A pair of electrodes are provided on the piezoelectric layer. The pair of electrodes face each other on the piezoelectric layer, and are connected to mutually different potentials. An alternating current (AC) voltage is applied between the electrodes to excite the bulk wave in the thickness shear mode.

### SUMMARY OF THE INVENTION

The acoustic wave device is, for example, an acoustic element such as an acoustic wave resonator. The acoustic wave resonator is used, for example, in a ladder filter. In order to obtain satisfactory characteristics in the ladder filter, it is necessary to increase an electrostatic capacitance ratio between a plurality of acoustic wave resonators. In this case, it is necessary an electrostatic capacitance of some acoustic wave resonators in the ladder filter.

In order to increase the electrostatic capacitance of the acoustic wave resonator, for example, it is necessary to increase a size of the acoustic wave resonator. Therefore, when the acoustic wave resonator is included in the ladder filter, a size of the ladder filter tends to increase. In particular, the size of the ladder filter having the acoustic wave resonator using a bulk wave in a thickness shear mode with small electrostatic capacitance increases.

The present inventors have discovered that, in a case where a configuration of the acoustic wave resonator has the following configuration, a suitable filter waveform can be obtained without increasing the size of the acoustic wave resonator in a case where the acoustic wave resonator is included in a filter device. The configuration is such that an electrode connected to a reference potential or the like, which is a potential different from an input potential and an output potential, is disposed between an electrode connected to the input potential and an electrode connected to the output potential.

In addition, the present inventors have also discovered that, in a case where another acoustic element is included in the filter device together with the acoustic wave resonator having the configuration described above, there is a concern that a filter characteristic may deteriorate.

Example embodiments of the present invention provide acoustic wave devices each capable of achieving a reduction in size of a filter device, and reducing or preventing a deterioration in filter characteristic.

According to an example embodiment of the present invention, an acoustic wave device includes a plurality of acoustic elements sharing a support, and a piezoelectric film that is provided on n the support and includes a piezoelectric layer including a piezoelectric body, the plurality of acoustic elements include a first acoustic element and a second acoustic element that is electrically connected to the first acoustic element, and the first acoustic element is an acoustic coupling filter, the first acoustic element includes a first comb-shaped electrode that is provided on the piezoelectric layer, includes a first busbar and a plurality of first electrode fingers each including one end connected to the first busbar, and is connected to an input potential, a second comb-shaped electrode that is provided on the piezoelectric layer, includes a second busbar and a plurality of second electrode fingers each including one end connected to the second busbar and interdigitated with the plurality of first electrode fingers, and is connected to an output potential, and a third electrode that includes a plurality of third electrode fingers which are provided on the piezoelectric layer to be arranged side by side with the first electrode fingers and the second electrode fingers in a direction in which the first electrode fingers and the second electrode fingers are arranged side by side when viewed in plan view and a connection electrode which connects the third electrode fingers adjacent to each other, the third electrode being connected to a potential different from the input potential to which the first comb-shaped electrode is connected and the output potential to which the second comb-shaped electrode is connected, an order in which a first electrode finger among the first electrode fingers, a second electrode finger among the second electrode fingers, and a third electrode finger among the third electrode fingers are arranged side by side is an order in which the first electrode finger, the third electrode finger, the second electrode finger, and the third electrode finger define one period in a case where the order is started from the first electrode finger, the second acoustic element includes a functional electrode that is provided on the piezoelectric layer, and an acoustic reflection portion is provided at a position in the support overlapping with the plurality of first electrode fingers, the plurality of second electrode fingers, and the plurality of third electrode fingers of the first acoustic element and the functional electrode of the second acoustic element in plan view.

According to example embodiments of the present invention, it is possible to provide acoustic wave devices each capable of achieving a reduction in size of a filter device, and reducing or preventing a deterioration in filter characteristic.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic elevational cross-sectional view of a first acoustic element and a second acoustic element according to the first example embodiment of the present invention.

FIG. 3 is a schematic plan view of the first acoustic element according to the first example embodiment of the present invention.

FIG. 4 is a schematic elevational cross-sectional view illustrating a vicinity of first to third electrode fingers according to the first example embodiment of the present invention.

FIG. 5 is a schematic plan view of the second acoustic element according to the first example embodiment of the present invention.

FIG. 6 is a graph illustrating a bandpass characteristic according to the first example embodiment of the present invention and a comparative example.

FIG. 7 is a view illustrating a map of a fractional bandwidth with respect to Euler angles (0°, θ, ψ) of LiNbO₃ in a case where d/p is infinitely close to 0.

FIG. 8 is a schematic plan view of a first acoustic element according to a modification example of the first example embodiment of the present invention.

FIG. 9 is a schematic plan view of a first acoustic element according to a second example embodiment of the present invention.

FIG. 10 is a schematic elevational cross-sectional view illustrating a vicinity of first to third electrode fingers according to the second example embodiment of the present invention.

FIG. 11 is a schematic elevational cross-sectional view of an acoustic wave device according to the second example embodiment of the present invention.

FIG. 12 is a schematic plan view of an acoustic wave device according to a third example embodiment of the present invention.

FIG. 13 is a schematic elevational cross-sectional view of an acoustic wave device according to a fourth example embodiment of the present invention.

FIG. 14 is a schematic plan view of an acoustic wave device according to a fifth example embodiment of the present invention.

FIG. 15 is a schematic elevational cross-sectional view of an acoustic wave device according to a first modification example of the fifth example embodiment of the present invention.

FIG. 16 is a schematic elevational cross-sectional view of an acoustic wave device according to a second modification example of the fifth example embodiment of the present invention.

FIG. 17 is a schematic elevational cross-sectional view of an acoustic wave device according to a third modification example of the fifth example embodiment of the present invention.

FIG. 18 is a schematic elevational cross-sectional view of an acoustic wave device according to a fourth modification example of the fifth example embodiment of the present invention.

FIG. 19 is a schematic plan view of an acoustic wave device according to a fifth modification example of the fifth example embodiment of the present invention.

FIG. 20A is a schematic perspective view illustrating an appearance of an acoustic wave device using a bulk wave in a thickness shear mode, and in FIG. 20B is a plan view illustrating an electrode structure on a piezoelectric layer.

FIG. 21 is a cross-sectional view of a portion taken along a line A-A in FIG. 20A.

FIG. 22A is a schematic elevational cross-sectional view for describing a Lamb wave that propagates through a piezoelectric film of the acoustic wave device, and in FIG. 22B is a schematic elevational cross-sectional view for describing a bulk wave in a thickness shear mode, which propagates through the piezoelectric film of the acoustic wave device.

FIG. 23 is a view illustrating an amplitude direction of the bulk wave in the thickness shear mode.

FIG. 24 is a view illustrating a resonance characteristic of the acoustic wave device using the bulk wave in the thickness shear mode.

FIG. 25 is a view illustrating a relationship between d/p and a fractional bandwidth as a resonator in a case where a center-to-center distance between electrodes adjacent to each other is defined as p and a thickness of a piezoelectric layer is defined as d.

FIG. 26 is a plan view of an acoustic wave device using the bulk wave in the thickness shear mode.

FIG. 27 is a view illustrating resonance characteristics of an acoustic wave device of a reference example in which spurious appears.

FIG. 28 is a view illustrating a relationship between a fractional bandwidth and a phase rotation amount of an impedance of the spurious standardized at 180 degrees as a magnitude of the spurious.

FIG. 29 is a view illustrating a relationship between d/2p and a metallization ratio MR.

FIG. 30 is a view illustrating the map of the fractional bandwidth with respect to Euler angles (0°, θ, ψ) of LiNbO₃ in a case where d/p is infinitely close to 0.

FIG. 31 is an elevational cross-sectional view of an acoustic wave device including an acoustic multilayer film.

FIG. 32 is a perspective view of a partial notch for describing an acoustic wave device using the Lamb wave.

### DETAILED DESCRIPTION OF THE EXAMPLE EMBODIMENTS

Hereinafter, the present invention will be elucidated by describing specific example embodiments of the present invention with reference to the drawings.

Each example embodiment described in the present specification is merely an example, and configurations can be partially replaced or combined with each other between different example embodiments.

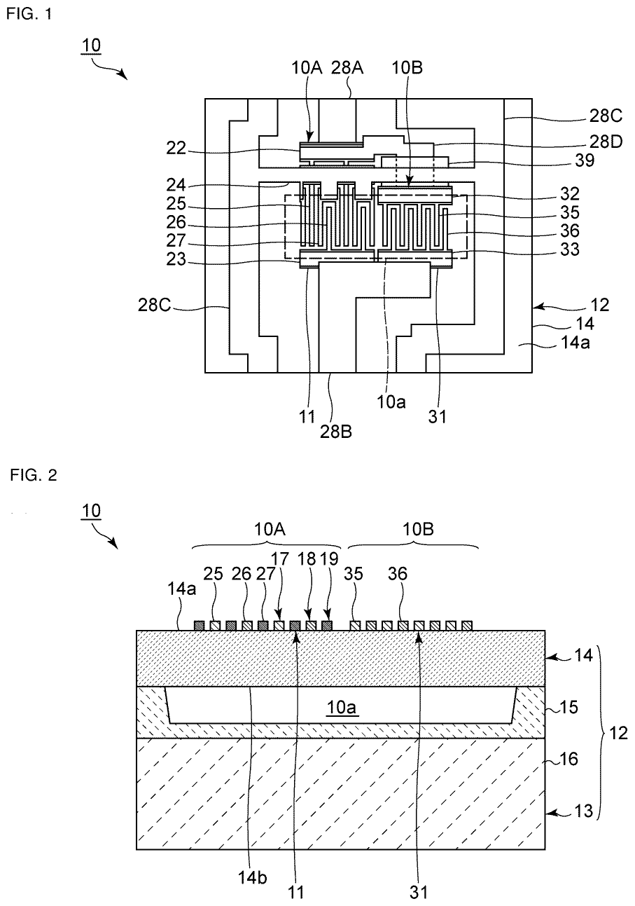

FIG. 1 is a schematic plan view of an acoustic wave device according to a first example embodiment of the present invention.

An acoustic wave device 10 is used as a portion of a filter device. The acoustic wave device 10 includes a plurality of acoustic elements. Meanwhile, an acoustic wave device according to an example embodiment of the present invention may be a filter device. Hereinafter, a configuration of the acoustic wave device 10 will be described.

The acoustic wave device 10 includes one first acoustic element 10A and one second acoustic element 10B. In the present example embodiment, both the first acoustic element 10A and the second acoustic element 10B are acoustic wave resonators, for example. Specifically, the first acoustic element 10A is an acoustic coupling filter. The first acoustic element 10A includes a functional electrode 11. The second acoustic element 10B is an acoustic wave resonator that is not an acoustic coupling filter. The second acoustic element 10B includes an interdigital transducer (IDT) electrode 31 as a functional electrode.

The number of the first acoustic element 10A and the second acoustic element 10B in the acoustic wave device 10 is not limited to the above. An acoustic wave device according to an example embodiment of the present invention may include at least one first acoustic element and at least one second acoustic element. The first acoustic element and the second acoustic element are electrically connected to each other.

In the acoustic wave device 10, the first acoustic element 10A and the second acoustic element 10B are connected in parallel. In the present example embodiment, the second acoustic element 10B is used as a trap element. The first acoustic element 10A and the second acoustic element 10B may be connected in series.

As illustrated in FIG. 1, the acoustic wave device 10 includes a piezoelectric substrate 12. The piezoelectric substrate 12 is a substrate having piezoelectricity. The piezoelectric substrate 12 includes a piezoelectric layer 14 as a piezoelectric film. The piezoelectric layer 14 is a layer including a piezoelectric body. On the other hand, in the present specification, the piezoelectric film is a film having piezoelectricity, and does not necessarily refer to a film including a piezoelectric body. Meanwhile, in the present example embodiment, the piezoelectric film is the single-layer piezoelectric layer 14, and is a film including a piezoelectric body. In an example embodiment of the present invention, the piezoelectric film may be a laminated film including the piezoelectric layer 14. In the present example embodiment, the piezoelectric substrate 12 is a multilayer body including the piezoelectric layer 14. The first acoustic element 10A and the second acoustic element 10B share the piezoelectric substrate 12. The first acoustic element 10A and the second acoustic element 10B share the piezoelectric layer 14 as the piezoelectric film.

The piezoelectric substrate 12 is provided with a cavity portion 10a. In the present example embodiment, at least a portion of the functional electrode 11 and at least a portion of the IDT electrode 31 overlap with the same cavity portion 10a when viewed in a lamination direction of the piezoelectric substrate 12.

Hereinafter, a configuration of the first acoustic element 10A, which is an acoustic coupling filter, will be specifically described.

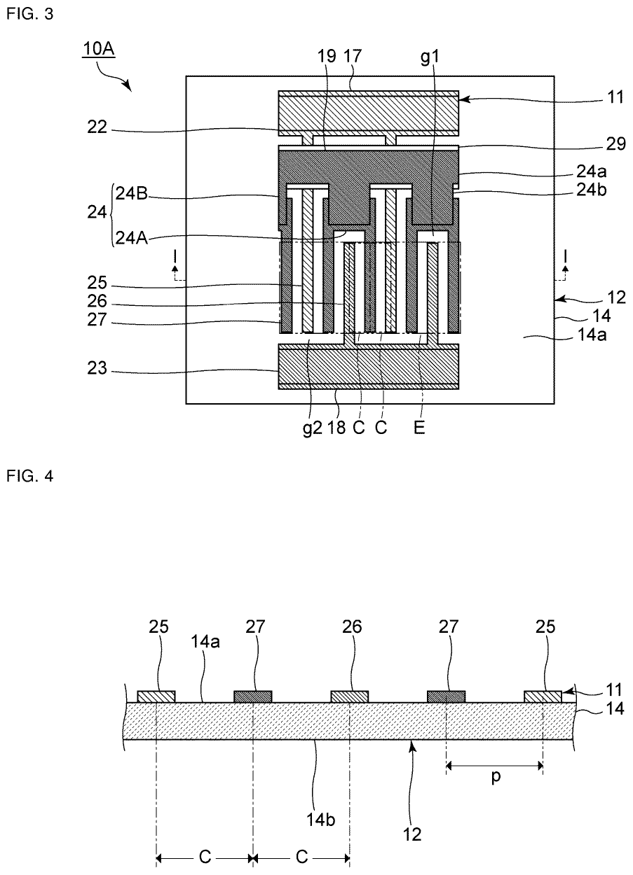

FIG. 2 is a schematic elevational cross-sectional view of the first acoustic element and the second acoustic element according to the first example embodiment. FIG. 3 is a schematic plan view of the first acoustic element according to the first example embodiment. FIG. 2 is a schematic cross-sectional view illustrating a portion including a cross-section taken along a line I-I in FIG. 3. In FIG. 2, each electrode is illustrated with hatching. In the schematic plan view other than FIG. 2, hatching may be applied to the electrodes in the same manner. In FIG. 3, a wiring connected to the first acoustic element 10A, the second acoustic element 10B, and the like are omitted.

As described above, the first acoustic element 10A illustrated in FIG. 2 includes the piezoelectric substrate 12 and the functional electrode 11. The piezoelectric substrate 12 includes a support 13, and the piezoelectric layer 14 as a piezoelectric film. In the present example embodiment, the support 13 includes a support substrate 16 and an insulating layer 15. The insulating layer 15 is provided on the support substrate 16. The piezoelectric layer 14 is provided on the insulating layer 15. Meanwhile, the support 13 may be configured with only the support substrate 16.

The piezoelectric layer 14 includes a first main surface 14a and a second main surface 14b. The first main surface 14a and the second main surface 14b face each other. The piezoelectric layer 14 and the support 13 overlap with each other when viewed in a direction in which the first main surface 14a and the second main surface 14b of the piezoelectric layer 14 face each other. Out of the first main surface 14a and the second main surface 14b, the second main surface 14b is located on the support 13 side. The functional electrode 11 is provided on the first main surface 14a of the piezoelectric layer 14.

As a material of the support substrate 16, for example, a semiconductor such as silicon, ceramics such as aluminum oxide, or the like can be used. As a material of the insulating layer 15, an appropriate dielectric such as silicon oxide or tantalum oxide can be used. For example, the piezoelectric layer 14 is a lithium niobate layer such as a LiNbO₃ layer, or a lithium tantalate layer such as a LiTaO₃ layer.

The insulating layer 15 is provided with a recess portion. The piezoelectric layer 14 as a piezoelectric film is provided on the insulating layer 15 to cover the recess portion. Therefore, a hollow portion is provided. The hollow portion includes the cavity portion 10a. In the present example embodiment, the support 13 and the piezoelectric film are disposed such that a portion of the support 13 and a portion of the piezoelectric film face each other with the cavity portion 10a interposed therebetween. Meanwhile, the recess portion at the support 13 may be provided over the insulating layer 15 and the support substrate 16. Alternatively, the recess portion provided only at the support substrate 16 may be closed by the insulating layer 15. The recess portion may be provided at the piezoelectric layer 14, for example. The cavity portion 10a may be a through-hole provided in the support 13.

The cavity portion 10a is an acoustic reflection portion. The acoustic reflection portion can effectively confine energy of acoustic waves of the first acoustic element 10A and the second acoustic element 10B to the piezoelectric layer 14 side. The acoustic reflection portion is provided at a position in the support 13 at which the acoustic reflection portion overlaps with at least a portion of the functional electrode 11 in plan view. In addition, as described above, the cavity portion 10a as the acoustic reflection portion overlaps with at least a portion of the IDT electrode 31 of the second acoustic element 10B in plan view.

In the present specification, the description of “in plan view” means that an object is viewed in a lamination direction of the support 13 and the piezoelectric film from a direction corresponding to an upward direction in FIG. 2. In FIG. 2, for example, the piezoelectric layer 14 side is an upper side out of the support substrate 16 side and the piezoelectric layer 14 side. Further, in the present specification, the plan view is synonymous with a view from a main surface facing direction. The main surface facing direction is a direction in which the first main surface 14a and the second main surface 14b of the piezoelectric layer 14 face each other. More specifically, the main surface facing direction is, for example, a direction normal to the first main surface 14a.

As illustrated in FIG. 3, the functional electrode 11 includes one pair of comb-shaped electrodes and a third electrode 19. Specifically, the pair of comb-shaped electrodes are a first comb-shaped electrode 17 and a second comb-shaped electrode 18. The first comb-shaped electrode 17 is connected to an input potential. The second comb-shaped electrode 18 is connected to an output potential. In the present example embodiment, the third electrode 19 is connected to a reference potential. In the present example embodiment, the third electrode 19 is a reference potential electrode. The third electrode 19 does not necessarily have to be connected to the reference potential. The third electrode 19 may be connected to a potential different from potentials to which the first comb-shaped electrode 17 and the second comb-shaped electrode 18 are connected. Meanwhile, it is preferable that the third electrode 19 is connected to the reference potential.

The first comb-shaped electrode 17 and the second comb-shaped electrode 18 are provided on the first main surface 14a of the piezoelectric layer 14. The first comb-shaped electrode 17 includes a first busbar 22 and a plurality of first electrode fingers 25. Each one end of the plurality of first electrode fingers 25 is connected to the first busbar 22. The second comb-shaped electrode 18 includes a second busbar 23 and a plurality of second electrode fingers 26. Each one end of the plurality of second electrode fingers 26 is connected to the second busbar 23.

The first busbar 22 and the second busbar 23 face each other. The plurality of first electrode fingers 25 and the plurality of second electrode fingers 26 are interdigitated with each other. The first electrode finger 25 and the second electrode finger 26 are alternately arranged side by side in a direction orthogonal to a direction in which the first electrode fingers 25 and the second electrode fingers 26 extend.

The third electrode 19 includes a third busbar 24 as a connection electrode and a plurality of third electrode fingers 27. The plurality of third electrode fingers 27 are provided on the first main surface 14a of the piezoelectric layer 14. The plurality of third electrode fingers 27 are electrically connected to each other by the third busbar 24.

Each of the plurality of third electrode fingers 27 is arranged side by side with the first electrode finger 25 and the second electrode finger 26 in a direction in which the first electrode fingers 25 and the second electrode fingers 26 are arranged side by side. Accordingly, the first electrode fingers 25, the second electrode fingers 26, and the third electrode fingers 27 are arranged side by side in one direction. The plurality of third electrode fingers 27 extend in parallel with the plurality of first electrode fingers 25 and the plurality of second electrode fingers.

In the following, a direction in which the first electrode finger 25, the second electrode finger 26, and the third electrode finger 27 extend is referred to as an electrode finger extending direction, and a direction orthogonal to the electrode finger extending direction is referred to as an electrode finger orthogonal direction. When a direction in which the first electrode fingers 25, the second electrode fingers 26, and the third electrode fingers 27 are arranged side by side is defined as an electrode finger arrangement direction, the electrode finger arrangement direction is parallel to the electrode finger orthogonal direction. In the present specification, the first electrode finger 25, the second electrode finger 26, and the third electrode finger 27 may be collectively and simply referred to as electrode fingers. The first busbar 22 and the second busbar 23 may be collectively and simply referred to as busbars.

FIG. 4 is a schematic elevational cross-sectional view illustrating a vicinity of the first to third electrode fingers according to the first example embodiment.

An order in which the plurality of electrode fingers are arranged side by side is an order in which the first electrode finger 25, the third electrode finger 27, the second electrode finger 26, and the third electrode finger 27 define one period in a case where the order is started from the first electrode finger 25. Therefore, the order in which the plurality of electrode fingers are arranged side by side is continued as the first electrode finger 25, the third electrode finger 27, the second electrode finger 26, the third electrode finger 27, the first electrode finger 25, the third electrode finger 27, the second electrode finger 26, and the like. In a case where the input potential is represented by IN, the output potential is represented by OUT, and the reference potential is represented by GND, and the order of the plurality of electrode fingers is represented by an order of the potentials to be connected, the order is continued as IN, GND, OUT, GND, IN, GND, OUT, and the like.

In the present example embodiment, in a region in which the plurality of electrode fingers are provided, electrode fingers located at both end portions in the electrode finger orthogonal direction are the third electrode fingers 27. In the region, the electrode finger located at the end portion in the electrode finger orthogonal direction may be any type of electrode finger among the first electrode finger 25, the second electrode finger 26, and the third electrode finger 27.

As illustrated in FIG. 3, the third busbar 24 as a connection electrode of the third electrode 19 electrically connects the plurality of third electrode fingers 27. Specifically, the third busbar 24 is located in a region between the first busbar 22 and tips of the plurality of second electrode fingers 26. The plurality of first electrode fingers 25 are also located in this region. Meanwhile, the third busbar 24 and the plurality of first electrode fingers 25 are electrically insulated from each other by an insulating film 29.

More specifically, the third busbar 24 includes a plurality first connection electrodes 24A and one second connection electrode 24B. Each of the first connection electrodes 24A connects tips of the two third electrode fingers 27 adjacent to each other. A U-shaped electrode is configured with the first connection electrode 24A and the two third electrode fingers 27. The second connection electrode 24B connects the plurality of first connection electrodes 24A. The insulating film 29 is provided between the second connection electrode 24B and the plurality of first electrode fingers 25.

More specifically, the insulating film 29 is provided on the first main surface 14a of the piezoelectric layer 14 to cover a portion of the plurality of first electrode fingers 25. The insulating film 29 is provided in a region between the first busbar 22 and the tips of the plurality of second electrode fingers 26. The insulating film 29 has a strip shape.

The insulating film 29 does not reach onto the first connection electrode 24A of the third electrode 19. Then, the second connection electrode 24B is provided over the insulating film 29 and over the plurality of first connection electrodes 24A. Specifically, the second connection electrode 24B includes a bar portion 24a and a plurality of projection portions 24b. Each of the projection portions 24b extends from the bar portion 24a toward each of the first connection electrodes 24A. Each of the projection portions 24b is connected to each of the first connection electrodes 24A. Therefore, the plurality of third electrode fingers 27 are electrically connected to each other by the first connection electrodes 24A and the second connection electrode 24B.

In the present example embodiment, the third busbar 24 is located in a region between the first busbar 22 and the tips of the plurality of second electrode fingers 26. Therefore, each of the tips of the plurality of second electrode fingers 26 faces the third busbar 24 with a gap g1 therebetween, in the electrode finger extending direction. On the other hand, each of tips of the plurality of first electrode fingers 25 faces the second busbar 23 with a gap g2 therebetween, in the electrode finger extending direction.

The third busbar 24 may be located in a region between the second busbar 23 and the tips of the plurality of first electrode fingers 25. In this case, each of the tips of the plurality of first electrode fingers 25 faces the third busbar 24 with a gap therebetween. On the other hand, each of the tips of the plurality of second electrode fingers 26 faces the first busbar 22 with a gap therebetween.

Thus, in a case where the third electrode 19 is a reference potential electrode, the first acoustic element 10A may be configured as follows. Each of the tips of the plurality of first electrode fingers 25 may face an electrode connected to a potential, which is a potential different from a potential to which the electrode finger is connected and is any of the input potential, the output potential, or the reference potential with a gap therebetween, in the electrode finger extending direction. In the same manner, each of the tips of the plurality of second electrode fingers 26 may face an electrode connected to a potential, which is a potential different from a potential to which the electrode finger is connected and is any of the input potential, the output potential, and the reference potential with a gap therebetween, in the electrode finger extending direction.

A dimension of these gaps in the electrode finger extending direction is defined as a gap length. In the present example embodiment, a gap length of the gap g1 and a gap length of the gap g2 are the same. Meanwhile, the gap length of the gap g1 and the gap length of the gap g2 may be different from each other.

The first acoustic element 10A is an acoustic wave resonator configured such that a bulk wave in a thickness shear mode can be used. As illustrated in FIG. 3, the first acoustic element 10A includes a plurality of excitation regions C. In the plurality of excitation regions C, a bulk wave in a thickness shear mode or an acoustic wave in other modes is excited. In FIG. 3, only two excitation regions C among the plurality of excitation regions C are illustrated.

A plurality of excitation regions C among all the excitation regions C are each a region in which the first electrode finger 25 and the third electrode finger 27 adjacent to each other overlap with each other when viewed from the electrode finger orthogonal direction and is a region between centers of the first electrode finger 25 and the third electrode finger 27 adjacent to each other. A plurality of remaining excitation regions C are each a region in which the second electrode finger 26 and the third electrode finger 27 adjacent to each other overlap with each other when viewed from the electrode finger orthogonal direction and a region between centers of the second electrode finger 26 and the third electrode finger 27 adjacent to each other. These excitation regions C are arranged side by side in the electrode finger orthogonal direction.

In the functional electrode 11, the configuration excluding the third electrode 19 is the same as the configuration of the IDT electrode. A region in which the first electrode fingers 25 and the second electrode fingers 26 adjacent to each other overlap with each other when viewed from the electrode finger orthogonal direction is an intersecting region E. Meanwhile, the intersecting region E can also be said to be a region in which the first electrode finger 25 and the third electrode finger 27 adjacent to each other or the second electrode finger 26 and the third electrode fingers 27 adjacent to each other overlap with each other when viewed from the electrode finger orthogonal direction. The intersecting region E includes the plurality of excitation regions C. The intersecting region E and the excitation region C are regions of the piezoelectric layer 14, which are defined based on the configuration of the functional electrode 11.

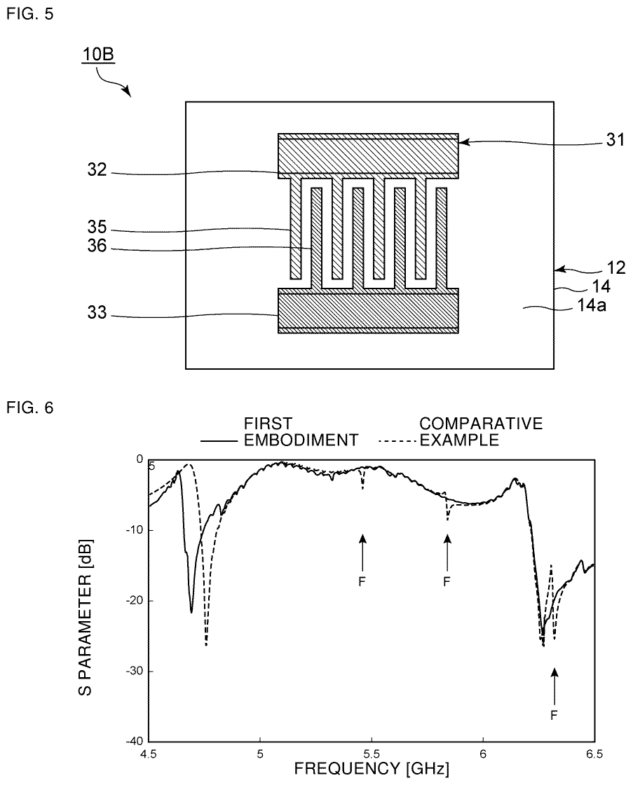

FIG. 5 is a schematic plan view of the second acoustic element according to the first example embodiment. In FIG. 5, a wiring or the like connected to the second acoustic element 10B or the first acoustic element 10A is omitted.

The second acoustic element 10B is configured such that a bulk wave in a thickness shear mode can be used. The second acoustic element 10B shares the piezoelectric substrate 12 with the first acoustic element 10A. The second acoustic element 10B has the IDT electrode 31. More specifically, the IDT electrode 31 is provided on the first main surface 14a of the piezoelectric layer 14 in the piezoelectric substrate 12.

As illustrated in FIG. 5, the IDT electrode 31 includes one pair of busbars and a plurality of electrode fingers. Specifically, the pair of busbars are a fourth busbar 32 and a fifth busbar 33. The fourth busbar 32 and the fifth busbar 33 face each other. Specifically, the plurality of electrode fingers are a plurality of fourth electrode fingers 35 and a plurality of fifth electrode fingers 36. One ends of the plurality of fourth electrode fingers 35 are connected to the fourth busbar 32. One ends of the plurality of fifth electrode fingers 36 are connected to the fifth busbar 33. The plurality of fourth electrode fingers 35 and the plurality of fifth electrode fingers 36 are interdigitated with each other.

Hereinafter, the fourth electrode finger 35 and the fifth electrode finger 36 may be collectively and simply referred to as electrode fingers. The fourth busbar 32 and the fifth busbar 33 may be collectively and simply referred to as busbars. In the second acoustic element 10B, a direction in which the fourth electrode finger 35 and the fifth electrode finger 36 extend is the electrode finger extending direction, and a direction orthogonal to the electrode finger extending direction is the electrode finger orthogonal direction.

The second acoustic element 10B also includes an excitation region and an intersecting region, in the same manner as the first acoustic element 10A. In the second acoustic element 10B, the excitation region is a region in which the fourth electrode finger 35 and the fifth electrode finger 36 adjacent to each other overlap with each other when viewed in the electrode finger orthogonal direction, and is a region between centers of the fourth electrode finger 35 and the fifth electrode finger 36 adjacent to each other. In the second acoustic element 10B, the intersecting region is a region in which the fourth electrode finger 35 and the fifth electrode finger 36 adjacent to each other overlap with each other when viewed from the electrode finger orthogonal direction. In the second acoustic element 10B, the intersecting region also includes a plurality of excitation regions.

Unique features of the present example embodiment are as follows. 1) The first acoustic element 10A which is an acoustic coupling filter and the second acoustic element 10B are provided. 2) In plan view, the cavity portion 10a overlaps with the plurality of first electrode fingers 25, the plurality of second electrode fingers 26, and the plurality of third electrode fingers 27 of the first acoustic element 10A, the plurality of fourth electrode fingers 35 and fifth electrode fingers 36 of the second acoustic element 10B. As a result, in a case where the acoustic wave device 10 is included in a filter device, a reduction in size of the filter device can be achieved and a deterioration in filter characteristic can be reduced or prevented. This will be illustrated below by comparing the present example embodiment and a comparative example.

The comparative example is different from the first example embodiment in that a cavity portion with which a functional electrode of a first acoustic element overlaps in plan view and a cavity portion with which an IDT electrode of a second acoustic element overlaps in plan view are provided individually. In the same manner as the first example embodiment, in the comparative example, the first acoustic element and the second acoustic element are connected in parallel. Bandpass characteristics in the first example embodiment and the comparative examples are compared.

FIG. 6 is a diagram illustrating the bandpass characteristics of the first example embodiment and the comparative example. The bandpass characteristic is indicated by an S (Scattering) parameter.

First, as illustrated in FIG. 6, it can be seen that a filter characteristic is obtained for the acoustic wave device 10 of the first example embodiment. The first acoustic element 10A in the acoustic wave device 10 is an acoustic coupling filter. More specifically, as illustrated in FIG. 3, the first acoustic element 10A includes the excitation region C located between the centers of the first electrode finger 25 and the third electrode finger 27 adjacent to each other and the excitation region C located between the centers of the second electrode finger 26 and the third electrode fingers 27 adjacent to each other. In these excitation regions C, acoustic waves of a plurality of modes including a bulk wave in a thickness shear mode are excited. By coupling these modes, a filter waveform can be suitably obtained.

Therefore, in a case where the acoustic wave device 10 is included in the filter device, a filter waveform can be suitably obtained even in a case where the number of acoustic wave resonators of the filter device is small. Therefore, it is possible to achieve a reduction in size of the filter device.

As indicated by an arrow F in FIG. 6, in the bandpass characteristic of the comparative example, a large ripple caused by an unnecessary wave occurs in a pass band. In the bandpass characteristic of the comparative example, a large ripple due to the unnecessary wave occurs even in a frequency range near the pass band, which is on a high band side with respect to the pass band. On the other hand, in the first example embodiment, it can be seen that an unnecessary wave is reduced or prevented in a pass band and in a band other than the pass band. In this manner, in the first example embodiment, a deterioration in filter characteristic can be reduced or prevented. The reason is as follows.

In the first example embodiment illustrated in FIG. 1, the functional electrode 11 of the first acoustic element 10A and the IDT electrode 31 of the second acoustic element 10B overlap with the same cavity portion 10a in plan view. As a result, the first acoustic element 10A which is an acoustic coupling filter and the second acoustic element 10B are acoustically gently coupled. In particular, an unnecessary wave occurring in the second acoustic element 10B is reduced by an influence of the first acoustic element 10A which is the acoustic coupling filter. Therefore, in the acoustic wave device 10, the unnecessary wave can be reduced or prevented.

Hereinafter, a configuration of the first example embodiment will be described in more detail.

As illustrated in FIG. 1, a first signal potential wiring 28A, a second signal potential wiring 28B, a reference potential wiring 28C, and a common connection wiring 28D are provided on the first main surface 14a of the piezoelectric layer 14. The first signal potential wiring 28A is connected to an input potential. The second signal potential wiring 28B is connected to an output potential. The reference potential wiring 28C is connected to a reference potential. The first busbar 22 of the first acoustic element 10A and the fourth busbar 32 of the second acoustic element 10B are connected in common at the common connection wiring 28D.

The first busbar 22 of the first acoustic element 10A is connected to the first signal potential wiring 28A. Then, the fourth busbar 32 of the second acoustic element 10B is electrically connected to the first signal potential wiring 28A via the common connection wiring 28D and the first busbar 22. Therefore, the first acoustic element 10A and the second acoustic element 10B are connected to the same input potential. The first signal potential wiring 28A and the common connection wiring 28D may be integral with each other.

The second busbar 23 of the first acoustic element 10A and the fifth busbar 33 of the second acoustic element 10B are connected in common to the second signal potential wiring 28B. Therefore, the first acoustic element 10A and the second acoustic element 10B are connected to the same output potential. In this manner, the first acoustic element 10A and the second acoustic element 10B are connected in parallel.

The third busbar 24 of the first acoustic element 10A, as a connection electrode, is connected to the reference potential wiring 28C. The third busbar 24 is connected to the reference potential via the reference potential wiring 28C.

In the first example embodiment, a three-dimensional wiring portion including the third busbar 24 and the common connection wiring 28D is configured. Specifically, the insulating film 39 is provided on the first main surface 14a of the piezoelectric layer 14 to cover a portion of the common connection wiring 28D. The common connection wiring 28D passes between the first main surface 14a and the insulating film 39, and is connected to the fourth busbar 32.

On the other hand, the third busbar 24 passes over the insulating film 39, and is connected to the reference potential wiring 28C. A portion of the common connection wiring 28D and a portion of the third busbar 24 face each other with the insulating film 39 interposed therebetween. Therefore, the three-dimensional wiring portion is configured. The common connection wiring 28D and the third busbar 24 are electrically insulated from each other. By providing the three-dimensional wiring portion, it is possible to simplify routing of the wiring. Therefore, the acoustic wave device 10 can be made small. Meanwhile, the three-dimensional wiring portion does not necessarily have to be configured.

In the same manner as the first example embodiment, it is preferable that the plurality of excitation regions C of the first acoustic element 10A overlap with the cavity portion 10a as the acoustic reflection portion, in plan view. As a result, energy of an acoustic wave in the first acoustic element 10A can be more reliably and effectively confined to the piezoelectric layer 14 side. It is preferable that a plurality of excitation regions of the second acoustic element 10B overlap with the cavity portion 10a as the acoustic reflection portion, in plan view. As a result, energy of an acoustic wave in the second acoustic element 10B can be more reliably and effectively confined to the piezoelectric layer 14 side.

In the first example embodiment, a plurality of respective excitation regions of the first acoustic element 10A and the second acoustic element 10B overlap with the same cavity portion 10a, in plan view. Therefore, the first acoustic element 10A and the second acoustic element 10B can be more reliably and acoustically gently coupled to each other.

The acoustic reflection portion may be an acoustic reflection film such as an acoustic multilayer film to be described below. For example, the acoustic reflection film may be provided on a surface of the support.

In the first example embodiment, in the first acoustic element 10A, a center-to-center distance between the first electrode finger 25 and the third electrode finger 27 adjacent to each other is the same as a center-to-center distance between the second electrode finger 26 and the third electrode finger 27 adjacent to each other. Meanwhile, the center-to-center distance between the first electrode finger 25 and the third electrode finger 27 adjacent to each other and the center-to-center distance between the second electrode finger 26 and the third electrode finger 27 adjacent to each other are not constant. In this case, the longest distance between a center-to-center distance between the first electrode finger 25 and the third electrode finger 27 adjacent to each other and a center-to-center distance between the second electrode finger 26 and the third electrode finger 27 adjacent to each other is defined as p. In a case where the center-to-center distance between the electrode fingers adjacent to each other is constant in the same manner as the first example embodiment, a center-to-center distance between any electrode fingers adjacent to each other is also the distance p.

In a case where a thickness of the piezoelectric film is defined as d, d/p is preferably about 0.5 or less, and more preferably about 0.24 or less, for example. Therefore, in the first acoustic element 10A, a bulk wave in the thickness shear mode is suitably excited. In the first example embodiment, the thickness d is a thickness of the piezoelectric layer 14.

In the second acoustic element 10B, in a case where the longest distance among the center-to-center distances of the fourth electrode finger 35 and the fifth electrode finger 36 adjacent to each other is denoted by p, it is preferable that d/p is about 0.5 or less, for example. d/p is more preferably about 0.24 or less, for example. Therefore, in the second acoustic element 10B, a bulk wave in the thickness shear mode is suitably excited. In the first example embodiment, all the center-to-center distances of the fourth electrode fingers 35 and the fifth electrode fingers 36 adjacent to each other are the same. In this case, a center-to-center distance between any electrode fingers adjacent to each other is also the distance p.

A first acoustic element according to an example embodiment of the present invention does not necessarily have to be configured such that the bulk wave in the thickness shear mode can be used. For example, a first acoustic element according to an example embodiment of the present invention may be configured to be capable of exciting a plate wave. In this case, an excitation region is the intersecting region E illustrated in FIG. 3. In the same manner, the second acoustic element may be configured to be capable of exciting a plate wave.

In the first example embodiment, the piezoelectric layer 14 is made of lithium niobate. In the present specification, the fact that a certain structural element or portion is made of a certain material includes a case where a trace amount of impurities is included to the extent that the electrical characteristics of the acoustic wave device do not significantly deteriorate. A fractional bandwidth of the first acoustic element 10A depends on Euler angles (φ, θ, ψ) of lithium niobate used in the piezoelectric layer 14. A fractional bandwidth is represented by (|fa−fr|/fr)×100 [%] in a case where a resonant frequency is defined as fr and an anti-resonant frequency is defined as fa.

A relationship between the fractional bandwidth of the first acoustic element 10A and Euler angles (φ, θ, ψ) of the piezoelectric layer 14 in a case where d/p is infinitely close to 0 is derived. φ in the Euler angles is set to 0°.

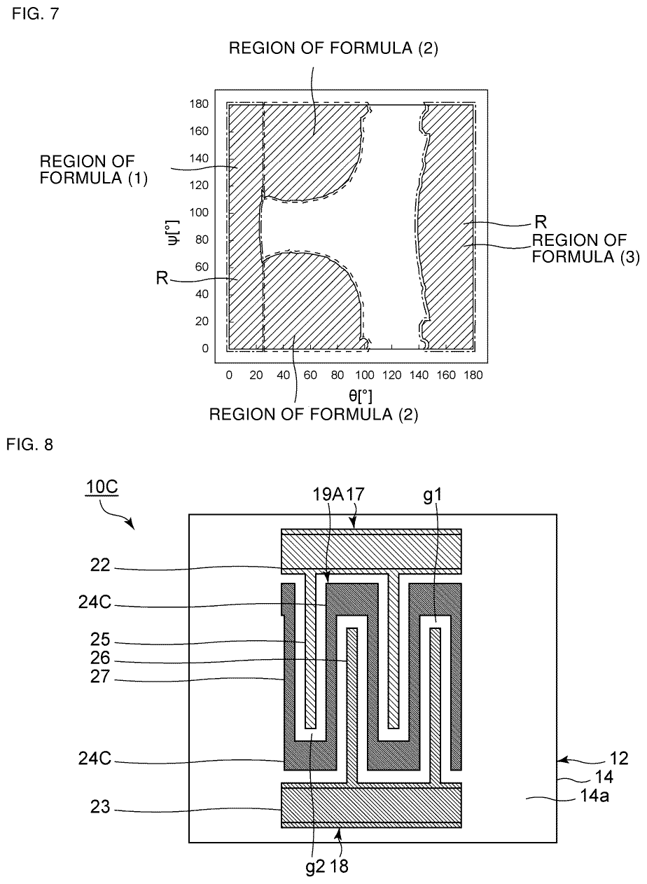

FIG. 7 is a view illustrating a map of a fractional bandwidth with respect to Euler angles (0°, θ, ψ) of LiNbO₃ in a case where d/p is infinitely close to 0.

A region R indicated by hatching in FIG. 7 is a region in which at least about 2% or more of a fractional bandwidth is obtained, for example. When a range of the region R is approximated, the range is a range represented by Formula (1), Formula (2), and Formula (3) below, for example. In a case where φ in Euler angles (φ, θ, ψ) is within a range of 0°+10°, a relationship between θ and ψ and the fractional bandwidth is the same as a relationship illustrated in FIG. 7. Even in a case where the piezoelectric layer 14 is a lithium tantalate layer, the relationship between θ and ψ in Euler angles (within a range of 0°±10°, θ, ψ) and the fractional bandwidth is the same as the relationship illustrated in FIG. 7.

(Within a range of 0°±10°, 0° to 25°, any ψ) Formula (1)

(Within a range of 0°±10°, 25° to 100°, 0° to 75° [(1−(θ−50)²/2500)]^{1/2} or 180°−75°[(1−(θ−50)²/2500)]^{1/2} to 180°) Formula (2)

(Within a range of 0°±10°, 180°−40° [(1−(ψ−90)²/8100)]^{1/2} to 180°, any ψ) Formula (3)

It is preferable that Euler angles are within the range of Formula (1), Formula (2), or Formula (3) described above. As a result, the fractional bandwidth can be sufficiently widened. Therefore, the acoustic wave device 10 including the first acoustic element 10A can be suitably used in a filter device.

As illustrated in FIG. 3, in the first example embodiment, the third electrode 19 includes the third busbar 24 as a connection electrode and the plurality of third electrode fingers 27. The third electrode 19 is a comb-shaped electrode. Meanwhile, the third electrode 19 does not necessarily have to be a comb-shaped electrode. For example, according to a modification example of the first example embodiment illustrated in FIG. 8, a third electrode 19A has a meandering shape. In the present modification example, the insulating film 29 is not provided on the piezoelectric layer 14. A connection electrode 24C includes only a portion corresponding to the plurality of first connection electrodes 24A according to the first example embodiment. The connection electrode 24C of the present modification example is not a third busbar.

More specifically, the third electrode 19A has a plurality of connection electrodes 24C located on the first busbar 22 side and a plurality of connection electrodes 24C located on the second busbar 23 side. Tip portions of the two adjacent third electrode fingers 27 on the first busbar 22 side or tip portions of the two adjacent third electrode fingers 27 on the second busbar 23 side are connected to each other by the connection electrode 24C. For example, the connection electrodes 24C are connected one by one to both a tip portion on the first busbar 22 side and a tip portion on the second busbar 23 side, of the third electrode finger 27 other than both ends in the electrode finger orthogonal direction among the plurality of third electrode fingers 27. This third electrode finger 27 is connected to the third electrode finger 27, on both sides thereof, by each of the connection electrodes 24C. The meandering shape of the third electrode 19A is formed by repeating this structure.

In the present modification example, a tip of each of the plurality of second electrode fingers 26 faces each of the plurality of connection electrodes 24C with the gap g1 therebetween, in the electrode finger extending direction. That is, each of the tips of the plurality of second electrode fingers 26 faces an electrode connected to a potential, which is a potential different from a potential to which the electrode finger is connected and is any of the input potential, the output potential, and the reference potential with the gap g1 therebetween, in the electrode finger extending direction. Specifically, the second electrode finger 26 is connected to the output potential, and the connection electrode 24C is connected to the reference potential. A dimension of the gap g1 between the tip of the second electrode finger 26 and the connection electrode 24C in the electrode finger extending direction is a gap length.

In the same manner, each of the tips of the plurality of first electrode fingers 25 faces each of the plurality of connection electrodes 24C with the gap g2 therebetween, in the electrode finger extending direction. That is, each of the tips of the plurality of first electrode fingers 25 faces an electrode connected to a potential, which is a potential different from a potential to which the electrode finger is connected and is any of the input potential, the output potential, and the reference potential with the gap g2 therebetween, in the electrode finger extending direction. Specifically, the first electrode finger 25 is connected to the input potential, and the connection electrode 24C is connected to the reference potential. A dimension of the gap g2 between the tip of the first electrode finger 25 and the connection electrode 24C in the electrode finger extending direction is a gap length.

In the present modification example, a gap length of the gap g1 and a gap length of the gap g2 are the same. Meanwhile, the gap length of the gap g1 and the gap length of the gap g2 may be different from each other.

In the present modification example as well, when viewed in plan view, a plurality of electrode fingers of the first acoustic element 10C and a plurality of electrode fingers of the second acoustic element 10B overlap with the same cavity portion 10a. As a result, in the same manner as the first example embodiment, in a case where the acoustic wave device is included in a filter device, a reduction in size of the filter device can be achieved and a deterioration in filter characteristic can be reduced or prevented.

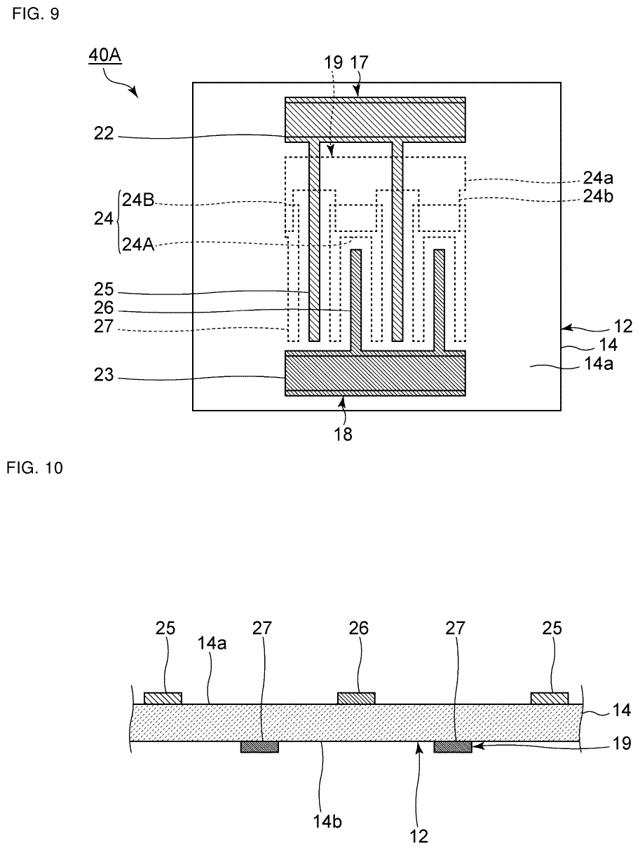

FIG. 9 is a schematic plan view of a first acoustic element according to a second example embodiment. FIG. 10 is a schematic elevational cross-sectional view illustrating a vicinity of first to third electrode fingers according to the second example embodiment.

As illustrated in FIGS. 9 and 10, the present example embodiment is different from the first example embodiment, in that the third electrode 19 is provided on the second main surface 14b of the piezoelectric layer 14. Except for the above point, the acoustic wave device according to the present example embodiment has the same configuration as the acoustic wave device 10 according to the first example embodiment.

In the present example embodiment, the arrangement of the third electrodes 19 in plan view is the same as that of the first example embodiment. Therefore, when viewed in plan view, the plurality of third electrode fingers 27 are provided on the second main surface 14b of the piezoelectric layer 14 to be arranged side by side with the first electrode fingers 25 and the second electrode fingers 26, in a direction in which the first electrode fingers 25 and the second electrode fingers 26 are arranged side by side. In plan view, an order in which the plurality of electrode fingers are arranged side by side is an order in which the first electrode finger 25, the third electrode finger 27, the second electrode finger 26, and the third electrode finger 27 define one period in a case where the order is started from the first electrode finger 25.

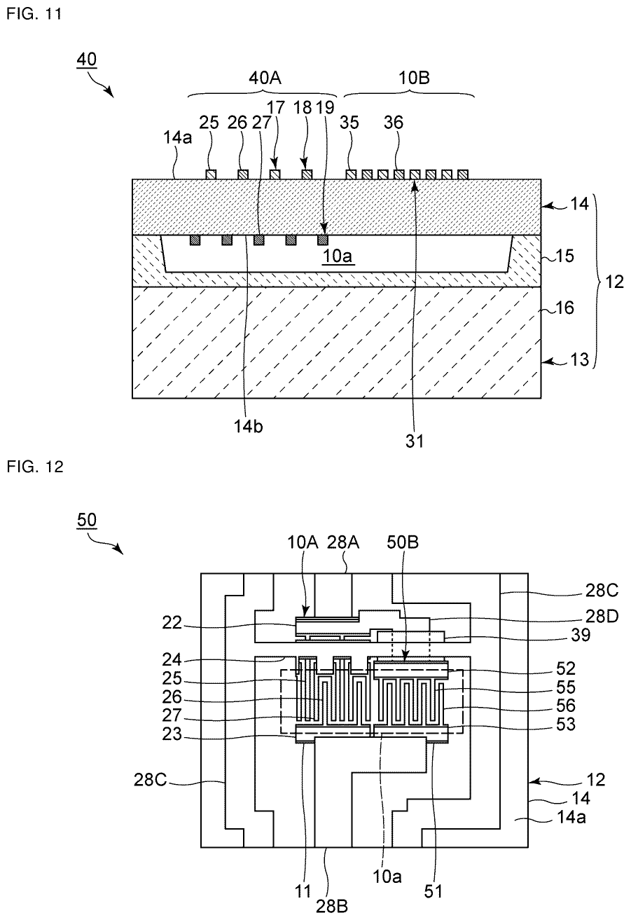

FIG. 11 is a schematic elevational cross-sectional view of an acoustic wave device according to the second example embodiment.

The third electrode 19 in a first acoustic element 40A is provided in the cavity portion 10a. Therefore, when viewed in plan, the plurality of third electrode fingers 27 of the first acoustic element 40A overlap with the cavity portion 10a. The plurality of first electrode fingers 25 and the plurality of second electrode fingers 26 also overlap with the cavity portion 10a in plan view. Further, the cavity portion 10a, and the plurality of fourth electrode fingers 35 and fifth electrode fingers 36 of the second acoustic element 10B overlap with each other in plan view. As a result, in the same manner as the first example embodiment, in a case where the acoustic wave device is included in a filter device, a reduction in size of the filter device can be achieved and a deterioration in filter characteristic can be reduced or prevented.

In the present example embodiment, an acoustic reflection portion includes the cavity portion 10a. Meanwhile, as described above, the acoustic reflection portion may include an acoustic reflection film. In this case, the third electrode finger 27 may be provided on the second main surface 14b of the piezoelectric layer 14 to be embedded in the acoustic reflection film.

Meanwhile, a second acoustic element according to an example embodiment of the present invention is not necessarily an acoustic wave resonator. This example is described with a third example embodiment.

FIG. 12 is a schematic plan view of an acoustic wave device according to a third example embodiment.

The present example embodiment is different from the first example embodiment, in that a second acoustic element 50B is a capacitive element. Except for the above point, an acoustic wave device 50 according to the present example embodiment has the same configuration as the acoustic wave device 10 according to the first example embodiment.

The second acoustic element 50B includes an IDT electrode 51 as a functional electrode. The IDT electrode 51 includes one pair of busbars and a plurality of electrode fingers. Specifically, the pair of busbars are a fourth busbar 52 and a fifth busbar 53. The fourth busbar 52 and the fifth busbar 53 face each other. Specifically, the plurality of electrode fingers are a plurality of fourth electrode fingers 55 and a plurality of fifth electrode fingers 56. One ends of the plurality of fourth electrode fingers 55 are connected to the fourth busbar 52. One ends of the plurality of fifth electrode fingers 56 are connected to the fifth busbar 53. The plurality of fourth electrode fingers 55 and the plurality of fifth electrode fingers 56 are interdigitated with each other.

An unnecessary wave may occur in a capacitive element in a filter device, and a filter characteristic may deteriorate. On the other hand, in the present example embodiment, the plurality of electrode fingers of the second acoustic element 50B which is a capacitive element and the plurality of electrode fingers of the first acoustic element 10A which is an acoustic coupling filter overlap with the same cavity portion 10a in plan view. As a result, the unnecessary wave can be reduced or prevented.

In the present example embodiment, as is the case for the first example embodiment, in a case where the acoustic wave device 50 is included in a filter device, a reduction in size of the filter device can be achieved and a deterioration in filter characteristic can be reduced or prevented.

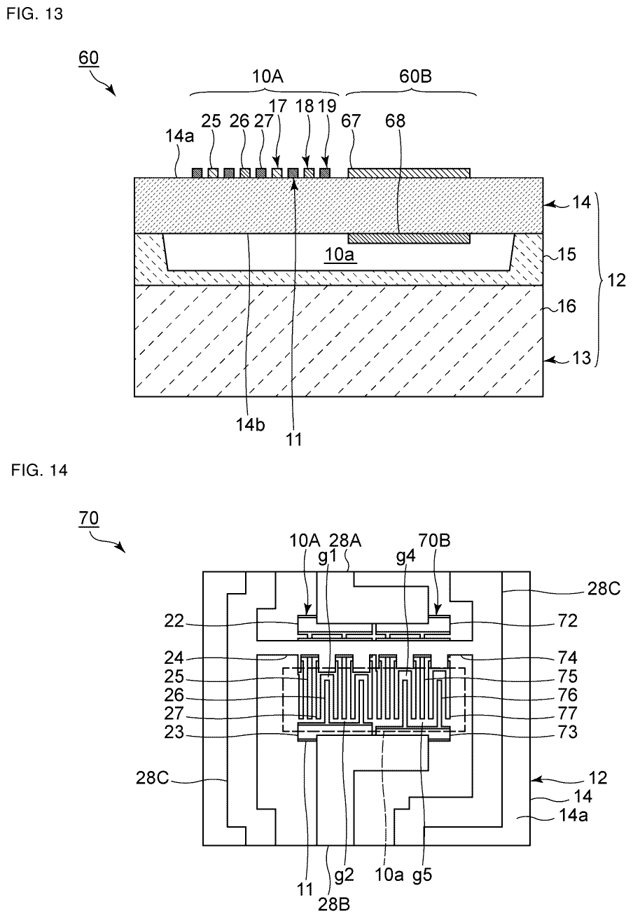

FIG. 13 is a schematic elevational cross-sectional view of an acoustic wave device according to a fourth example embodiment.

The present example embodiment is different from the first example embodiment, in that a second acoustic element 60B is a bulk wave resonator. In the present example embodiment, a configuration of a wiring is also different from that of the first example embodiment. Except for the above points, an acoustic wave device 60 according to the present example embodiment has the same configuration as the acoustic wave device 10 according to the first example embodiment.

A functional electrode of the second acoustic element 60B includes a fourth electrode 67 and a fifth electrode 68 as a first electrode and a second electrode. The fourth electrode 67 is provided on the first main surface 14a of the piezoelectric layer 14. The fifth electrode 68 is provided on the second main surface 14b of the piezoelectric layer 14. The fourth electrode 67 and the fifth electrode 68 face each other with the piezoelectric layer 14 interposed therebetween. In the piezoelectric layer 14, a region interposed between the fourth electrode 67 and the fifth electrode 68 is an excitation region.

The fifth electrode 68 in the second acoustic element 60B is provided in the cavity portion 10a. Therefore, in plan view, the fifth electrode 68 of the second acoustic element 60B overlaps with the cavity portion 10a. The fourth electrode 67 also overlaps with the cavity portion 10a in plan view. Further, the plurality of first electrode fingers 25, the plurality of second electrodes 26 and the plurality of third electrode fingers 27 of the first acoustic element 10A overlap with the cavity portion 10a in plan view. As a result, in the same manner as the first example embodiment, in a case where the acoustic wave device is included in a filter device, a reduction in size of the filter device can be achieved and a deterioration in filter characteristic can be reduced or prevented.

In the acoustic wave device 60, the fourth electrode 67 of the second acoustic element 60B and the first comb-shaped electrode 17 of the first acoustic element 10A are connected to the same input potential. The fourth electrode 67 and the first comb-shaped electrode 17 are connected to each other by a wiring provided on the first main surface 14a of the piezoelectric layer 14.

The fifth electrode 68 of the second acoustic element 60B and the second comb-shaped electrode 18 of the first acoustic element 10A are connected to the same output potential. For example, a through-electrode passing through the piezoelectric layer 14 may be provided. The fifth electrode 68 and the second comb-shaped electrode 18 may be electrically connected to each other via the through-electrode and an appropriate wiring.

In the present example embodiment, an acoustic reflection portion includes the cavity portion 10a. Meanwhile, the acoustic reflection portion may include an acoustic reflection film. In this case, the fifth electrode 68 may be provided on the second main surface 14b of the piezoelectric layer 14 to be embedded in the acoustic reflection film.

FIG. 14 is a schematic plan view of an acoustic wave device according to a fifth example embodiment.

The present example embodiment is different from the first example embodiment, in that a second acoustic element 70B is an acoustic coupling filter. The first signal potential wiring 28A is configured integrally with a common connection wiring, which is different from the first example embodiment. Except for the above points, an acoustic wave device 70 according to the present example embodiment has the same configuration as the acoustic wave device 10 according to the first example embodiment.

The first acoustic element 10A and the second acoustic element 70B are connected in parallel to each other. The first acoustic element 10A and the second acoustic element 70B are not split resonators obtained by splitting one acoustic wave resonator in parallel.

The second acoustic element 70B includes a first comb-shaped electrode, a second comb-shaped electrode, and a third electrode, which are independent from the first acoustic element 10A. Hereinafter, the first comb-shaped electrode of the second acoustic element 70B will be referred to as a fourth comb-shaped electrode. The second comb-shaped electrode of the second acoustic element 70B will be referred to as a fifth comb-shaped electrode. The third electrode of the second acoustic element 70B will be referred to as a sixth electrode.

The fourth comb-shaped electrode is connected to an input potential. The fifth comb-shaped electrode is connected to an output potential. In the present example embodiment, the sixth electrode is connected to a reference potential. In the present example embodiment, the sixth electrode is a reference potential electrode. The sixth electrode does not necessarily have to be connected to the reference potential. The sixth electrode may be connected to a potential different from potentials to which the fourth comb-shaped electrode and the fifth comb-shaped electrode are connected. Meanwhile, it is preferable that the sixth electrode is connected to the reference potential.

The fourth comb-shaped electrode and the fifth comb-shaped electrode are provided on the first main surface 14a of the piezoelectric layer 14. The fourth comb-shaped electrode includes a fourth busbar 72 as a first busbar and a plurality of fourth electrode fingers 75 as a plurality of first electrode fingers. Each one end of the plurality of fourth electrode fingers 75 is connected to the fourth busbar 72. The fifth comb-shaped electrode has a fifth busbar 73 as a second busbar and a plurality of fifth electrode fingers 76 as a plurality of second electrode fingers. Each one end of the plurality of fifth electrode fingers 76 is connected to the fifth busbar 73.

The fourth busbar 72 and the fifth busbar 73 face each other. The plurality of fourth electrode fingers 75 and the plurality of fifth electrode fingers 76 are interdigitated with each other. The fourth electrode finger 75 and the fifth electrode finger 76 are alternately arranged side by side in a direction orthogonal to a direction in which the fourth electrode fingers 75 and the fifth electrode fingers 76 extend.

The sixth electrode includes a sixth busbar 74 as a connection electrode and a plurality of sixth electrode fingers 77 as a plurality of third electrode fingers. The plurality of sixth electrode fingers 77 are provided on the first main surface 14a of the piezoelectric layer 14. The plurality of sixth electrode fingers 77 are electrically connected to each other by the sixth busbar 74. The sixth busbar 74 is configured in the same manner as the third busbar 24 of the first acoustic element 10A. Therefore, the sixth busbar includes a first connection electrode and a second connection electrode.

Each of the plurality of sixth electrode fingers 77 is arranged side by side with the fourth electrode finger 75 and the fifth electrode finger 76 in a direction in which the fourth electrode fingers 75 and the fifth electrode fingers 76 are arranged side by side. Accordingly, the fourth electrode fingers 75, the fifth electrode fingers 76, and the sixth electrode fingers 77 are arranged side by side in one direction. The plurality of sixth electrode fingers 77 extend in parallel with the plurality of fourth electrode fingers 75 and the plurality of second electrode fingers.

In the second acoustic element 70B, a direction in which the fourth electrode finger 75, the fifth electrode finger 76, and the sixth electrode finger 77 extend is the electrode finger extending direction, and a direction orthogonal to the electrode finger extending direction is the electrode finger orthogonal direction. Hereinafter, the fourth electrode finger 75, the fifth electrode finger 76, and the sixth electrode finger 77 may be collectively referred to as a plurality of electrode fingers.

An order in which the plurality of electrode fingers in the second acoustic element 70B are arranged side by side is an order in which the fourth electrode finger 75, the sixth electrode finger 77, the fifth electrode finger 76, and the sixth electrode finger 77 define one period in a case where the order is started from the fourth electrode finger 75.

The sixth busbar 74 is located in a region between the fourth busbar 72 and tips of the plurality of fifth electrode fingers 76. The sixth busbar 74 and the plurality of fourth electrode fingers 75 are electrically insulated from each other by an insulating film.

Each of the tips of the plurality of fifth electrode fingers 76 faces the sixth busbar 74 with a gap g4 therebetween, in the electrode finger extending direction. On the other hand, each of tips of the plurality of fourth electrode fingers 75 faces the fifth busbar 73 with a gap g5 therebetween, in the electrode finger extending direction.

In a case where the sixth electrode is the reference potential electrode, the second acoustic element 70B may be configured as follows, in the same manner as the first acoustic element 10A. Each of the tips of the plurality of fourth electrode fingers 75 may face an electrode connected to a potential, which is a potential different from a potential to which the electrode finger is connected and is any of the input potential, the output potential, or the reference potential with a gap therebetween, in the electrode finger extending direction. In the same manner, each of the tips of the plurality of fifth electrode fingers 76 may face an electrode connected to a potential, which is a potential different from a potential to which the electrode finger is connected and is any of the input potential, the output potential, and the reference potential with a gap therebetween, in the electrode finger extending direction.

A dimension of these gaps in the electrode finger extending direction is a gap length of the second acoustic element 70B. In the present example embodiment, a gap length of the gap g4 and a gap length of a gap g5 are the same. Meanwhile, the gap length of the gap g4 and the gap length of the gap g5 may be different from each other.

In the same manner as the first example embodiment, in the first acoustic element 10A, a gap length of the gap g1 and a gap length of the gap g2 are the same. Meanwhile, the gap length of the gap g1 and the gap length of the gap g2 may be different from each other.

In the present example embodiment, gap lengths between the first acoustic element 10A and the second acoustic element 70B are different from each other.

The second acoustic element 70B includes a plurality of excitation regions and an intersecting region, in the same manner as the first acoustic element 10A. Specifically, a plurality of excitation regions among all the excitation regions are each a region in which the fourth electrode finger 75 and the sixth electrode finger 77 adjacent to each other overlap with each other when viewed from the electrode finger orthogonal direction and is a region between centers of the fourth electrode finger 75 and the sixth electrode finger 77 adjacent to each other. A plurality of remaining excitation regions are each a region in which the fifth electrode finger 76 and the sixth electrode finger 77 adjacent to each other overlap with each other when viewed from the electrode finger orthogonal direction and a region between centers of the fifth electrode finger 76 and the sixth electrode finger 77 adjacent to each other. These excitation regions are arranged side by side in the electrode finger orthogonal direction.

A region in which the fourth electrode fingers 75 and the fifth electrode fingers 76 adjacent to each other overlap with each other when viewed from the electrode finger orthogonal direction is an intersecting region. Meanwhile, the intersecting region can also be said to be a region in which the fourth electrode finger 75 and the sixth electrode finger 77 adjacent to each other or the fifth electrode finger 76 and the sixth electrode finger 77 adjacent to each other overlap with each other when viewed from the electrode finger orthogonal direction.

The plurality of first electrode fingers 25, the plurality of second electrode fingers 26, and the plurality of third electrode fingers 27 in the first acoustic element 10A overlap with the cavity portion 10a in plan view. The plurality of fourth electrode fingers 75, the plurality of fifth electrode fingers 76, and the plurality of sixth electrode fingers 77 in the second acoustic element 70B overlap with the cavity portion 10a in plan view. As a result, in the same manner as the first example embodiment, in a case where the acoustic wave device is included in a filter device, a reduction in size of the filter device can be achieved and a deterioration in filter characteristic can be reduced or prevented.

As illustrated in FIG. 14, in the present example embodiment, the third busbar 24 of the first acoustic element 10A and the sixth busbar 74 of the second acoustic element 70B are integrated with each other. The third busbar 24 and the sixth busbar 74 are connected to the reference potential via the reference potential wiring 28C. Therefore, the wiring can be simplified, and a reduction in size of a filter device can be effectively achieved.

In a case where both the first acoustic element 10A and the second acoustic element 70B are acoustic coupling filters, the first acoustic element 10A and the second acoustic element 70B need only be different from each other in at least one of the following parameters. Specifically, the parameters are the total number of plurality of electrode fingers, a center-to-center distance between electrode fingers adjacent to each other, a width of the electrode finger, a thickness of the electrode finger, a gap length, and an intersecting width. The width of the electrode finger is a dimension of the electrode finger in the electrode finger orthogonal direction. The intersecting width is a dimension of the intersecting region in the electrode finger extending direction.

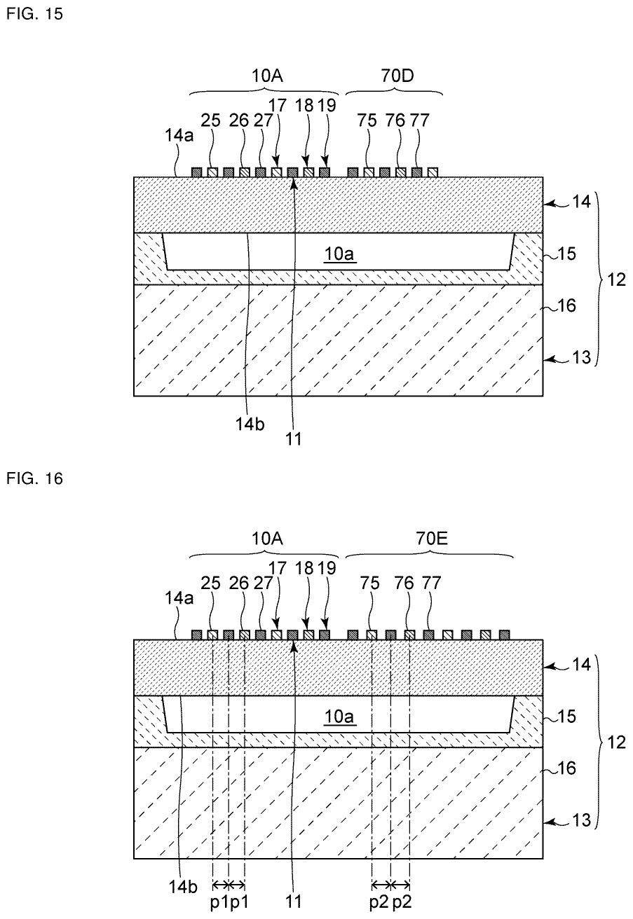

In the fifth example embodiment, the first acoustic element 10A and the second acoustic element 70B have different gap lengths. On the other hand, in a first modification example of the fifth example embodiment illustrated in FIG. 15, for the first acoustic element 10A and a second acoustic element 70D, the total numbers of plurality of electrode fingers are different from each other. Specifically, the total number of the plurality of first electrode fingers 25, the plurality of second electrode fingers 26, and the plurality of third electrode fingers 27 is different from the total number of the plurality of fourth electrode fingers 75, the plurality of fifth electrode fingers 76, and the plurality of sixth electrode fingers 77.

In a second modification example of the fifth example embodiment illustrated in FIG. 16, for the first acoustic element 10A and a second acoustic element 70E, center-to-center distances of electrode fingers adjacent to each other are different from each other. Specifically, a center-to-center distance between the first electrode finger 25 and the third electrode finger 27 adjacent to each other and a center-to-center distance between the second electrode finger 26 and the third electrode finger 27 adjacent to each other are set as a center-to-center distance p1. A center-to-center distance between the fourth electrode finger 75 the sixth electrode finger 77 adjacent to each other and a center-to-center distance between the fifth electrode finger 76 and the sixth electrode finger 77 adjacent to each other are defined as a center-to-center distance p2. In the present modification example, the center-to-center distance p1 in the first acoustic element 10A is constant. In the same manner, in the second acoustic element 70E, the center-to-center distance p2 is constant. Then, p1≠p2.

In the first acoustic element 10A, the center-to-center distance p1 does not have to be constant. In this case, the distance p in the first acoustic element 10A and the center-to-center distance p2 in the second acoustic element 10B may be different from each other. The distance p in the first acoustic element 10A is the longest distance among the center-to-center distance between the first electrode finger 25 and the third electrode finger 27 adjacent to each other and the center-to-center distance between the second electrode finger 26 and the third electrode finger 27 adjacent to each other. In a case where the center-to-center distance p1 is constant, all the center-to-center distances p1 are the distance p.

Alternatively, in the second acoustic element 70E, the center-to-center distance p2 does not have to be constant. In this case, the distance p in the second acoustic element 70E and the center-to-center distance p1 in the first acoustic element 10A may be different from each other. On the other hand, in a case where both the center-to-center distance p1 and the center-to-center distance p2 are not constant, the distance p in the first acoustic element 10A and the distance p in the second acoustic element 70E may be different from each other. In the present specification, the fact that the center-to-center distances are different from each other means that an absolute value of a difference between the center-to-center distances is about 1% or more with respect to any center-to-center distance, for example.

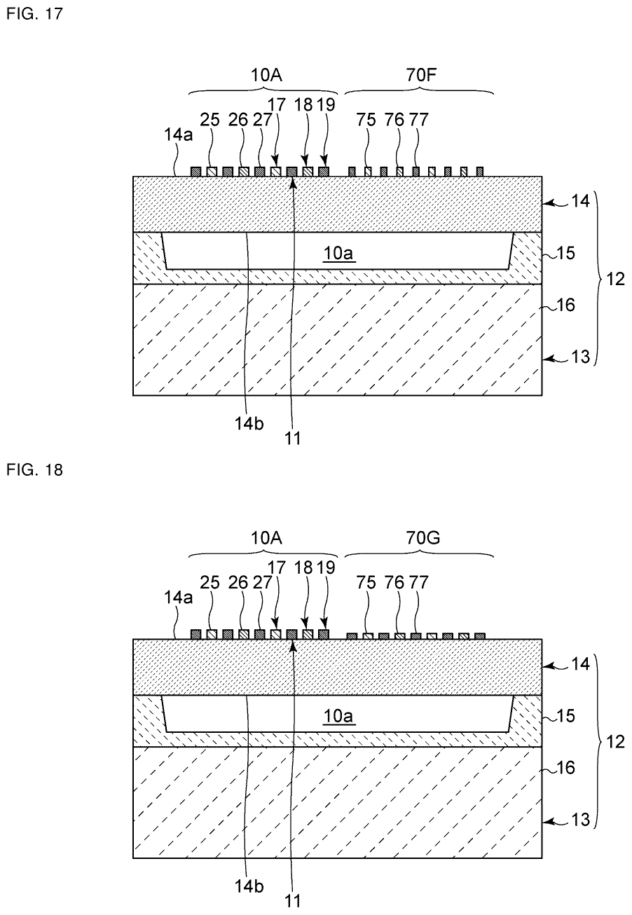

In a third modification example of the fifth example embodiment illustrated in FIG. 17, widths of electrode fingers in the first acoustic element 10A and a second acoustic element 70F are different from each other. Specifically, the widths of the first electrode finger 25, the second electrode finger 26, and the third electrode finger 27 in the first acoustic element 10A and the widths of the fourth electrode finger 75, the fifth electrode finger 76, and the sixth electrode finger 77 in the second acoustic element 70F are different from each other. In the present specification, the fact that the widths of the electrode fingers are different from each other means that an absolute value of a difference between the widths is about 1% or more with respect to any width, for example.

In a fourth modification example of the fifth example embodiment illustrated in FIG. 18, thicknesses of electrode fingers are different from each other, in the first acoustic element 10A and a second acoustic element 70G. Specifically, the thicknesses of the first electrode finger 25, the second electrode finger 26, and the third electrode finger 27 in the first acoustic element 10A are different from the thicknesses of the fourth electrode finger 75, the fifth electrode finger 76, and the sixth electrode finger 77 in the second acoustic element 70G. In the present specification, the fact that the thicknesses the electrode fingers are different from each other means that an absolute value of a difference between the thicknesses is about 1% or more with respect to any thickness, for example.

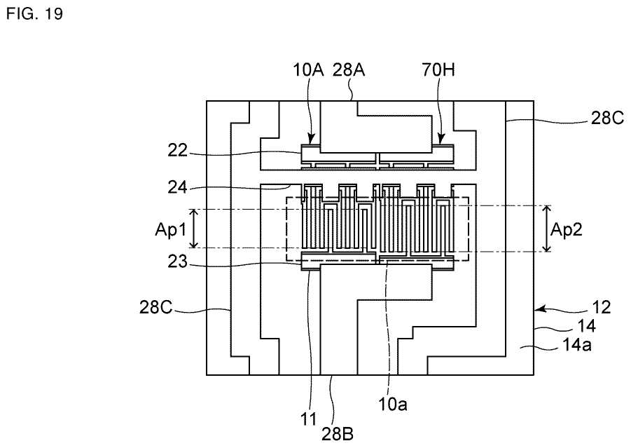

In a fifth modification example of the fifth example embodiment illustrated in FIG. 19, intersecting widths in the first acoustic element 10A and a second acoustic element 70H are different from each other. Specifically, in a case where the intersecting width in the first acoustic element 10A is denoted by Ap1 and the intersecting width in the second acoustic element 70H is denoted by Ap2, Ap1≠Ap2 is satisfied. In the present specification, the fact that the intersecting widths are different from each other means that an absolute value of a difference between the intersecting widths is about 1% or more with respect to any intersecting width, for example.

In the first to fifth modification examples, as is the case for the fifth example embodiment, in a case where the acoustic wave device is included in a filter device, a reduction in size of the filter device can be further achieved, and a deterioration in filter characteristic can be reduced or prevented.

Hereinafter, details of the thickness shear mode will be described by using an example in which a functional electrode is an IDT electrode. The “electrode” in the IDT electrode (to be described below) corresponds to the electrode finger. An acoustic wave device in the following example is one acoustic wave resonator. The support in the following example corresponds to a support substrate according to an example embodiment of the present invention. Hereinafter, a reference potential may be referred to as a ground potential.

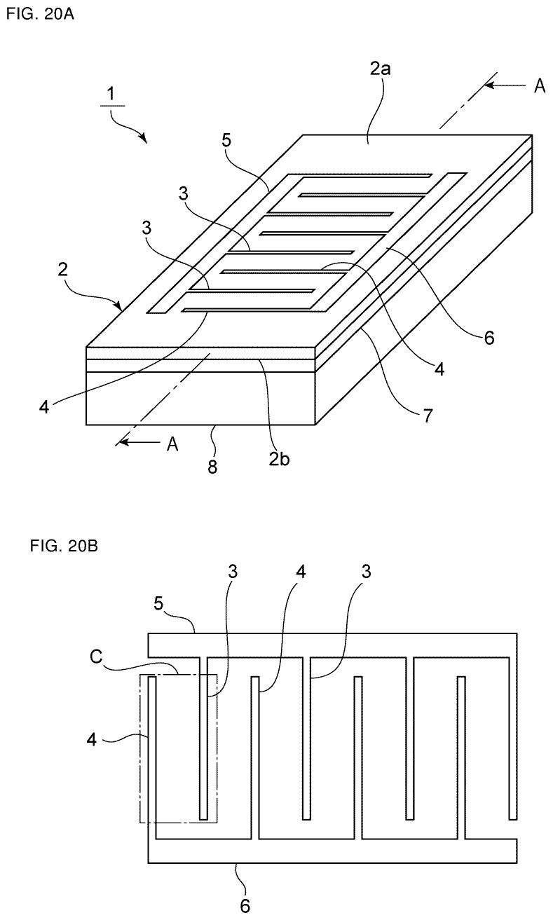

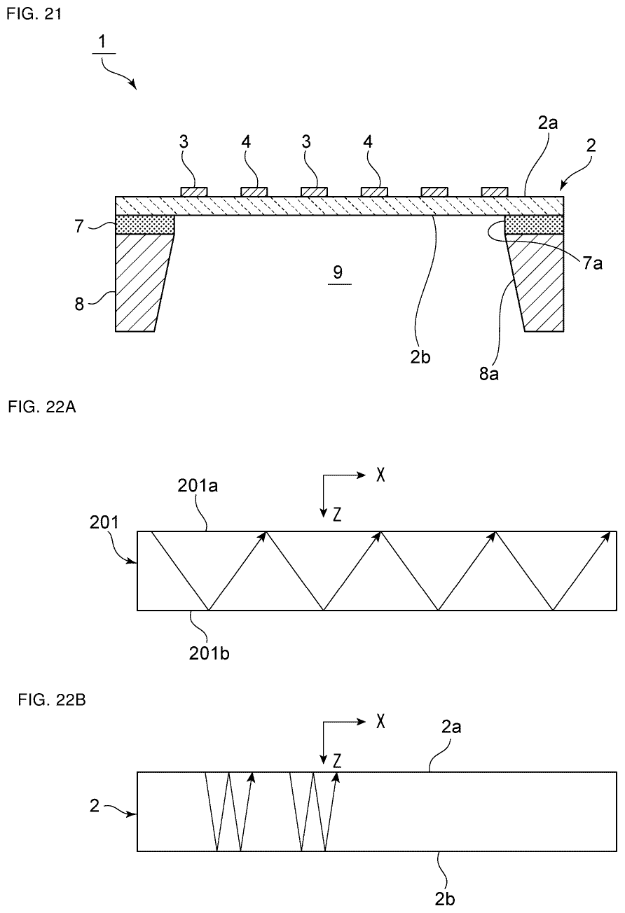

FIG. 20A is a schematic perspective view illustrating an appearance of an acoustic wave device using a bulk wave in a thickness shear mode and FIG. 20B is a plan view illustrating an electrode structure on a piezoelectric layer, and FIG. 21 is a cross-sectional view of a portion taken along a line A-A in FIG. 20A.

An acoustic wave device 1 includes a piezoelectric layer 2 made of LiNbO₃. The piezoelectric layer 2 may be made of LiTaO₃. Cut-angles of LiNbO₃ or LiTaO₃ are Z-cut, and may be a rotated Y-cut or X-cut. A thickness of the piezoelectric layer 2 is not particularly limited, and is preferably about 40 nm or larger and about 1000 nm or less, and more preferably about 50 nm or larger and about 1000 nm or less, for example, to effectively excite the thickness shear mode. The piezoelectric layer 2 includes first and second main surfaces 2a and 2b facing each other. Electrode 3 and electrode 4 are provided on the first main surface 2a. Here, the electrode 3 is an example of a “first electrode”, and the electrode 4 is an example of a “second electrode”. In FIGS. 20A and 20B, a plurality of electrodes 3 are connected to a first busbar 5. A plurality of electrodes 4 are connected to a second busbar 6. The plurality of electrodes 3 and the plurality of electrodes 4 are interdigitated with each other. The electrode 3 and the electrode 4 have a rectangular shape, and have a length direction. The electrode 3 and the electrode 4 adjacent thereto face each other in a direction orthogonal to the length direction. Both the length direction of the electrodes 3 and 4 and the direction orthogonal to the length direction of the electrodes 3 and 4 are directions intersecting the thickness direction of the piezoelectric layer 2. Therefore, it can be said that the electrode 3 and the electrode 4 adjacent thereto face each other in the direction intersecting the thickness direction of the piezoelectric layer 2. In addition, the length direction of the electrodes 3 and 4 may be changed to the direction orthogonal to the length direction of the electrodes 3 and 4 illustrated in FIGS. 20A and 20B. That is, in FIGS. 20A and 20B, the electrodes 3 and 4 may extend in a direction in which the first busbar 5 and the second busbar 6 extend. In this case, the first busbar 5 and the second busbar 6 extend in a direction in which the electrodes 3 and 4 extend in FIGS. 20A and 20B. A plurality of pairs of structures in which the electrode 3 connected to one potential and the electrode 4 connected to the other potential are adjacent to each other are provided in a direction orthogonal to the length direction of the electrodes 3 and 4. Here, a case where the electrodes 3 and 4 are adjacent to each other does not mean a case where the electrodes 3 and 4 are disposed to be in direct contact with each other, but means a case where the electrodes 3 and 4 are disposed with a distance interposed therebetween. In addition, in a case where the electrodes 3 and 4 are adjacent to each other, the electrode connected to a hot electrode or a ground electrode, including the other electrodes 3 and 4, is not disposed between the electrodes 3 and 4. The number of pairs does not need to be integer pairs, and may be 1.5 pairs, 2.5 pairs, or the like, for example. A center-to-center distance, that is, a pitch between the electrodes 3 and 4 is preferably in a range of about 1 μm or larger and about 10 μm or less, for example. In addition, the widths of the electrodes 3 and 4, that is, the dimensions of the electrodes 3 and 4 in the facing direction are preferably in a range of about 50 nm or larger and about 1000 nm or less, and more preferably in a range of about 150 nm or larger and about 1000 nm or less, for example. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal to the length direction of the electrode 4.

In addition, in the acoustic wave device 1, since the Z-cut piezoelectric layer is used, the direction orthogonal to the length direction of the electrodes 3 and 4 is a direction orthogonal to a polarization direction of the piezoelectric layer 2. This is not the case if a piezoelectric body of another cut-angle is used as the piezoelectric layer 2. Here, the description of “orthogonal” is not limited to being strictly orthogonal, and may be substantially orthogonal (an angle between the direction orthogonal to the length direction of the electrodes 3 and 4 and the polarization direction falls within a range of about 90°+10°, for example).

A support 8 is laminated on the second main surface 2b side of the piezoelectric layer 2 with an insulating layer 7 interposed therebetween. The insulating layer 7 and the support 8 have a frame shape and have through-holes 7a and 8a as e illustrated in FIG. 21. In this manner, a cavity portion 9 is provided. The cavity portion 9 enables free vibration of the excitation region C of the piezoelectric layer 2. Therefore, the support 8 is laminated on the second main surface 2b with the insulating layer 7 interposed therebetween, at a position not overlapping with the portion at which at least one pair of electrodes 3 and 4 are provided. The insulating layer 7 does not have to be provided. Therefore, the support 8 can be directly or indirectly laminated on the second main surface 2b of the piezoelectric layer 2.

The insulating layer 7 is made of silicon oxide. Meanwhile, in addition to silicon oxide, an appropriate insulating material such as silicon oxynitride or alumina can be used. The support 8 is made of Si. A plane orientation of a surface of Si on the piezoelectric layer 2 side may be (100), (110), or (111). It is desirable that Si forming the support 8 is high resistance having a resistivity of about 4 kΩcm or higher, for example. Meanwhile, the support 8 can also be made of an appropriate insulating material or semiconductor material.

Examples of the material of the support 8 include piezoelectric bodies such as aluminum oxide, lithium tantalate, lithium niobate, or quartz crystal, various ceramics such as alumina, magnesia, sapphire, silicon nitride, aluminum nitride, silicon carbide, zirconia, cordierite, mullite, steatite, or forsterite, dielectrics such as diamond or glass, or semiconductors such as gallium nitride.

The plurality of electrodes 3 and 4 and the first and second busbars 5 and 6 are made of appropriate metals or alloys such as Al or AlCu alloys. In the acoustic wave device 1, the electrodes 3 and 4 and the first and second busbars 5 and 6 have a structure in which an Al film is laminated on a Ti film. An adhesion layer other than the Ti film may be used.

During driving, the AC voltage is applied between the plurality of electrodes 3 and the plurality of electrodes 4. More specifically, the alternating current voltage is applied between the first busbar 5 and the second busbar 6. In this manner, it is possible to obtain the resonance characteristics using the bulk wave in the thickness shear mode excited in the piezoelectric layer 2. In addition, in the acoustic wave device 1, in a case where the thickness of the piezoelectric layer 2 is defined as d and the center-to-center distance between any electrodes 3 and 4 adjacent to each other in the plurality of pairs of electrodes 3 and 4 is defined as p, d/p is about 0.5 or less, for example. In this manner, the bulk wave in the thickness shear mode is effectively excited, and satisfactory resonance characteristics can be obtained. More preferably, d/p is about 0.24 or less, for example, and in this case, more satisfactory resonance characteristics can be obtained.

In the acoustic wave device 1, since the configuration described above is provided, even in a case where the number of pairs of the electrodes 3 and 4 is reduced in order to reduce the size, the Q factor is unlikely to be decreased. The reason is that a propagation loss is small even when the number of electrode fingers in reflectors on both sides is reduced. In addition, the number of electrode fingers can be reduced by using the bulk wave in the thickness shear mode. A difference between a Lamb wave used in the acoustic wave device and a bulk wave in the thickness shear mode will be described with reference to FIGS. 22A and 22B.

FIG. 22A is a schematic elevational cross-sectional view illustrating the Lamb wave that propagates through the piezoelectric film of the acoustic wave device as described in Japanese Unexamined Patent Application Publication No. 2012-257019. Here, the wave propagates in a piezoelectric film 201 as indicated by arrows. Here, in the piezoelectric film 201, a first main surface 201a and a second main surface 201b face each other, and the thickness direction connecting the first main surface 201a and the second main surface 201b is a Z-direction. An X-direction is a direction in which the electrode fingers of the IDT electrodes are arranged side by side. As illustrated in FIG. 22A, in the Lamb wave, the wave propagates in the X-direction as illustrated in the figure. Since the wave is a plate wave, the piezoelectric film 201 vibrates as a whole. Since the wave propagates in the X-direction, the reflectors are disposed on both sides to obtain the resonance characteristics. Therefore, the propagation loss of the wave occurs, and the Q factor is decreased in a case where a size reduction is attempted, that is, in a case where the number of pairs of the electrode fingers is decreased.

On the other hand, as illustrated in FIG. 22B, in the acoustic wave device 1, since the vibration displacement is a thickness shear direction, the wave substantially propagates and resonates in the direction connecting the first main surface 2a and the second main surface 2b of the piezoelectric layer 2, that is, the Z-direction. That is, an X-direction component of the wave is significantly smaller than a Z-direction component. Since the resonance characteristics are obtained by the propagation of the wave in the Z-direction, the propagation loss is less likely to occur even when the number of the electrode fingers of the reflector is reduced. Further, even in a case where the number of pairs of the electrode pair including the electrodes 3 and 4 is reduced when the size reduction is attempted, the Q factor is unlikely to be decreased.

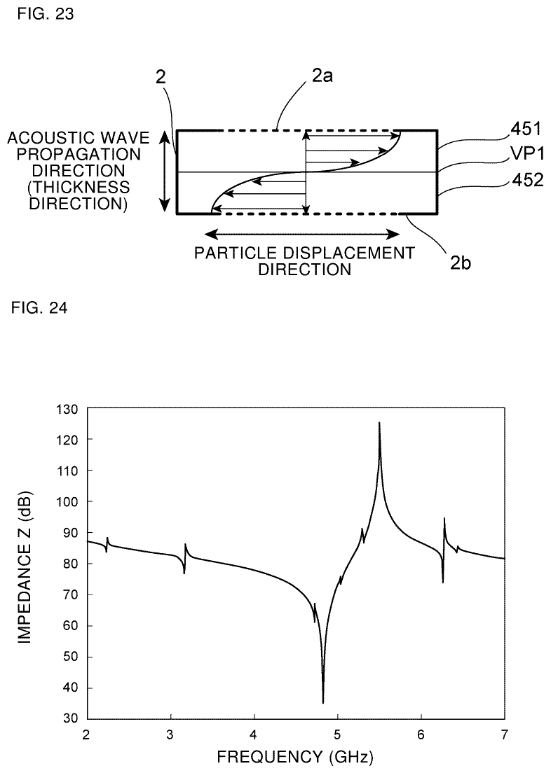

Amplitude directions of the bulk waves of the thickness shear mode are opposite to each other between a first region 451 included in the excitation region C of the piezoelectric layer 2 and a second region 452 included in the excitation region C, as illustrated in FIG. 23. FIG. 23 schematically illustrates the bulk waves in a case where the voltage is applied between the electrodes 3 and 4 such that the potential of the electrode 4 is higher than the potential of the electrode 3. The first region 451 is a region of the excitation region C between a virtual plane VP1, which is orthogonal to the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least one pair of electrodes including the electrodes 3 and 4 are disposed, the waves are not propagated in the X-direction, and thus the number of pairs of the electrode pair including the electrodes 3 and 4 does not have to be plural. That is, at least one pair of electrodes may be provided.

For example, the electrode 3 is an electrode connected to a hot potential and the electrode 4 is an electrode connected to a ground potential. Meanwhile, the electrode 3 may be connected to the ground potential and the electrode 4 may be connected to the hot potential. In the acoustic wave device 1, at least one pair of electrodes are the electrodes connected to the hot potential or the electrodes connected to the ground potential, as described above, and no floating electrodes are provided.

FIG. 24 is a view illustrating the resonance characteristics of the acoustic wave device illustrated in FIG. 21. Non-limiting examples of the design parameters of the acoustic wave device 1 with the resonance characteristics are as follows.

Piezoelectric layer 2: LiNbO₃ with Euler angles (0°, 0°, 90°), thickness=400 nm.

When viewed in the direction orthogonal to the length direction of the electrodes 3 and 4, the length of the region in which the electrodes 3 and 4 overlap with each other, that is, the length of the excitation region C=40 μm, the number of pairs of the electrodes including the electrodes 3 and 4=21 pairs, the center-to-center distance between the electrodes=3 μm, the width of the electrodes 3 and 4=500 nm, and d/p=0.133.

Insulating layer 7: silicon oxide film having the thickness of 1 μm.

Support 8: Si.

The length of the excitation region C is the dimension of excitation region C in the length direction of the electrodes 3 and 4.

In the acoustic wave device 1, an electrode-to-electrode distance of the electrode pair including the electrodes 3 and 4 is made equal in all the plurality of pairs. That is, the electrodes 3 and 4 are disposed at regular pitches.

As is clear from FIG. 24, good resonance characteristics with the fractional bandwidth of about 12.5% are obtained despite there being no reflectors, for example.

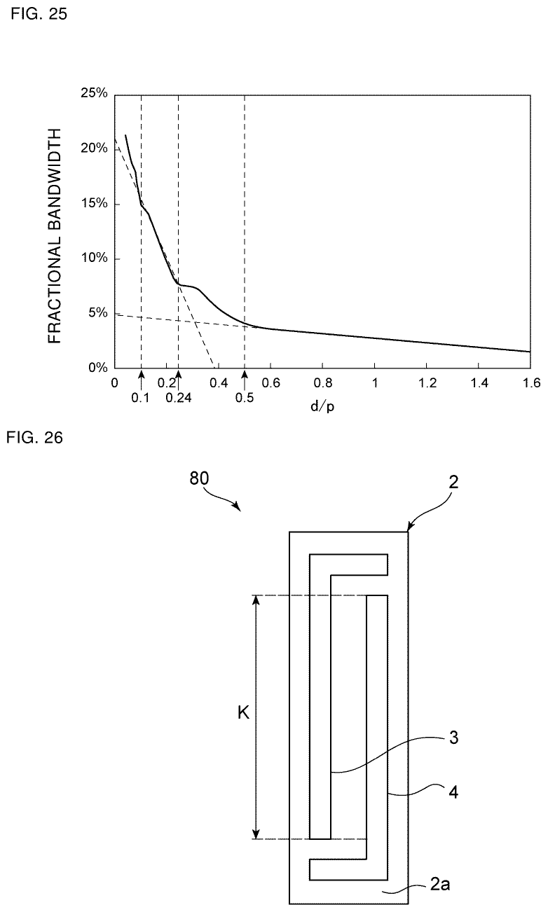

In a case where the thickness of the piezoelectric layer 2 is defined as d and the center-to-center distance between the electrodes 3 and 4 is defined as p, in the acoustic wave device 1, as described above, d/p is about 0.5 or less, more preferably about 0.24 or less, for example. The description thereof will be made with reference to FIG. 25.

A plurality of acoustic wave devices are obtained by changing d/p in the same manner as the acoustic wave device that obtains the resonance characteristics illustrated in FIG. 24. FIG. 25 is a view illustrating a relationship between d/p and the fractional bandwidth as the resonator of the acoustic wave device.

As is clear from FIG. 25, when d/p>about 0.5, the fractional bandwidth is less than about 58, for example, even in a case where d/p is adjusted. On the other hand, in a case where d/p≥about 0.5, when d/p is changed within this range, the fractional bandwidth of about 5% or more can be obtained, for example, that is, the resonator having a high coupling coefficient can be formed. In addition, in a case where d/p is about 0.24 or less, the fractional bandwidth can be increased to about 7% or larger, for example. In addition, when d/p is adjusted within this range, a resonator having a wider fractional bandwidth can be obtained, and a resonator having a higher coupling coefficient can be realized. Therefore, it can be understood that, by adjusting d/p to about 0.5 or less, for example, it is possible to configure a resonator having a high coupling coefficient using the bulk wave in the thickness shear mode.

FIG. 26 is a plan view of an acoustic wave device using the bulk wave in the thickness shear mode. In an acoustic wave device 80, one pair of electrodes including the electrode 3 and electrode 4 are provided on the first main surface 2a of the piezoelectric layer 2. K in FIG. 26 is an intersecting width. As described above, in the acoustic wave device according to the present invention, the number of pairs of the electrodes may be one pair. In this case as well, when d/p is about 0.5 or less, for example, it is possible to effectively excite the bulk wave in the thickness shear mode.

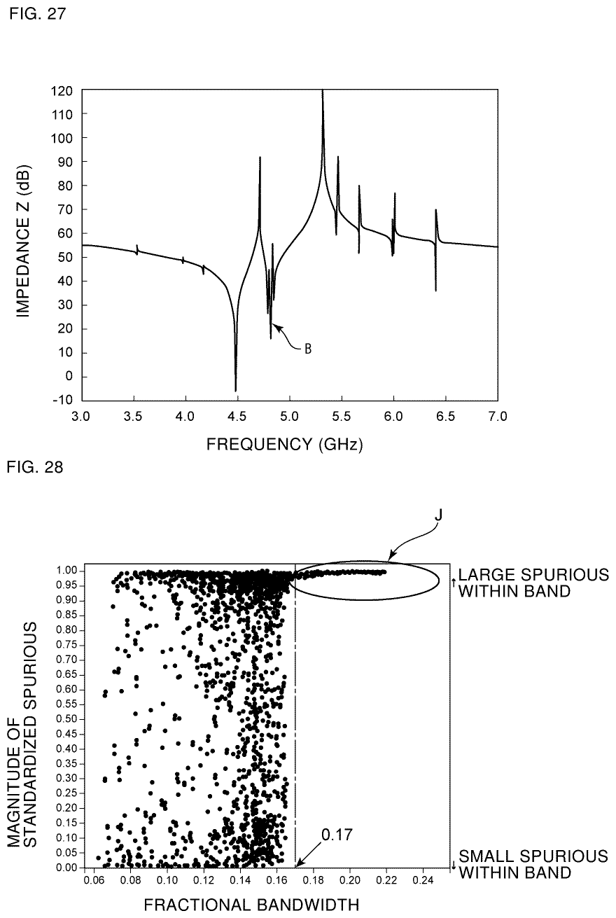

In the acoustic wave device 1, preferably, it is desirable that the metallization ratio MR of any adjacent electrodes 3 and 4 in the plurality of electrodes 3 and 4 to the excitation region C, which is the region in which the adjacent electrodes 3 and 4 overlap with each other when viewed in the facing direction, satisfies MR≤about 1.75 (d/p)+0.075, for example. In this case, the spurious can be effectively reduced. The description thereof will be made with reference to FIGS. 27 and 28. FIG. 27 is a reference view illustrating an example of the resonance characteristics of the acoustic wave device 1. The spurious indicated by an arrow B appears between the resonant frequency and the anti-resonant frequency. d/p=about 0.08 and the Euler angles of LiNbO₃ are (0°, 0°, 90°), for example. In addition, the metallization ratio MR is about 0.35, for example.

The metallization ratio MR will be described with reference to FIG. 20B. In the electrode structure in FIG. 20B, it is assumed that, when focusing on one pair of electrodes 3 and 4, only the pair of electrodes 3 and 4 are provided. In this case, a portion surrounded by a one-dot chain line is the excitation region C. When the electrode 3 and the electrode 4 are viewed in the direction orthogonal to the length direction of the electrodes 3 and 4, that is, in the facing direction, the excitation region C is a region that overlaps with the electrode 4 in the electrode 3, a region that overlaps with the electrode 3 in the electrode 4, and a region in which the electrode 3 and the electrode 4 overlap with each other in the region between the electrode 3 and the electrode 4. An area of the electrodes 3 and 4 inside the excitation region C with respect to an area of the excitation region C is the metallization ratio MR. That is, the metallization ratio MR is a ratio of an area of the metallization portion to the area of the excitation region C.

In a case where the plurality of pairs of electrodes are provided, MR may be a ratio of the metallization portion included in the entire excitation region to a total area of the excitation region.

FIG. 28 is a view illustrating a relationship between the fractional bandwidth and a phase rotation amount of the impedance of the spurious standardized at 180 degrees as a magnitude of the spurious when a large number of acoustic wave resonators are formed in accordance with the configuration of the acoustic wave device 1. The fractional bandwidth is adjusted by changing a film thickness of the piezoelectric layer and the dimensions of the electrodes. In addition, FIG. 28 illustrates the results in a case where the piezoelectric layer made of the Z-cut LiNbO₃ is used, and the same tendency is obtained in a case where piezoelectric layers with other cut-angles are used.

In a region surrounded by an ellipse J in FIG. 28, the spurious is as large as about 1.0, for example. As is clear from FIG. 28, in a case where the fractional bandwidth exceeds about 0.17, that is, exceeds about 178, for example, a large spurious with a spurious level of about 1 or more appears in a pass band even when the parameters constituting the fractional bandwidth are changed. That is, as in the resonance characteristics illustrated in FIG. 27, a large spurious indicated by an arrow B appears within the band. Therefore, the fractional bandwidth is preferably about 17% or less, for example. In this case, by adjusting the film thickness of the piezoelectric layer 2, the dimensions of the electrodes 3 and 4, or the like, the spurious can be reduced.

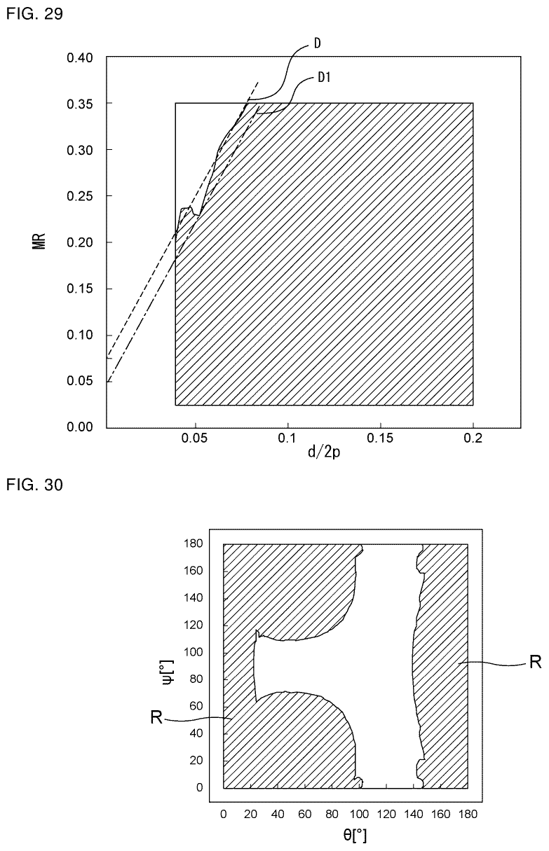

FIG. 29 is a view illustrating a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 29 is a region in which the fractional bandwidth is about 17% or less, for example. A boundary between the hatched region and a non-hatched region is expressed by MR=about 3.5 (d/2p)+0.075, for example. That is, MR=about 1.75 (d/p)+0.075, for example. Therefore, preferably, MR≤about 1.75 (d/p)+0.075, for example. In this case, it is easy to set the fractional bandwidth to about 17% or less, for example. A region on a right side of MR=about 3.5 (d/2p)+0.05, for example, indicated by a one-dot chain line D1 in FIG. 29 is more preferable. That is, when MR≤about 1.75 (d/p)+0.05, the fractional bandwidth can be reliably set to about 17% or less, for example.

FIG. 30 is a view illustrating a map of a fractional bandwidth with respect to Euler angles (0°, θ, ψ) of LiNbO₃ in a case where d/p is infinitely close to 0. Each of a plurality of regions R illustrated in FIG. 30 with hatching is a region in which a fractional bandwidth of about 2% or more is obtained, for example. In a case where φ in Euler angles (φ, θ, ψ) is within a range of 0°+5°, for example, a relationship between θ and ψ and the fractional bandwidth is the same as the relationship illustrated in FIG. 30. In a case where a piezoelectric layer is made of lithium tantalate (LiTaO₃) as well, the relationship between θ and ψ in Euler angles (within a range of 0°±5°, θ, ψ) and BW is the same as the relationship illustrated in FIG. 30.

Therefore, in a case where φ of the Euler angles (φ, θ, ψ) of lithium niobate or lithium tantalate of the piezoelectric layer is within a range of 0°±5° and θ and φ are within a range of any of a plurality of regions R illustrated in FIG. 30, for example, the fractional bandwidth can be sufficiently widened, which is preferable.

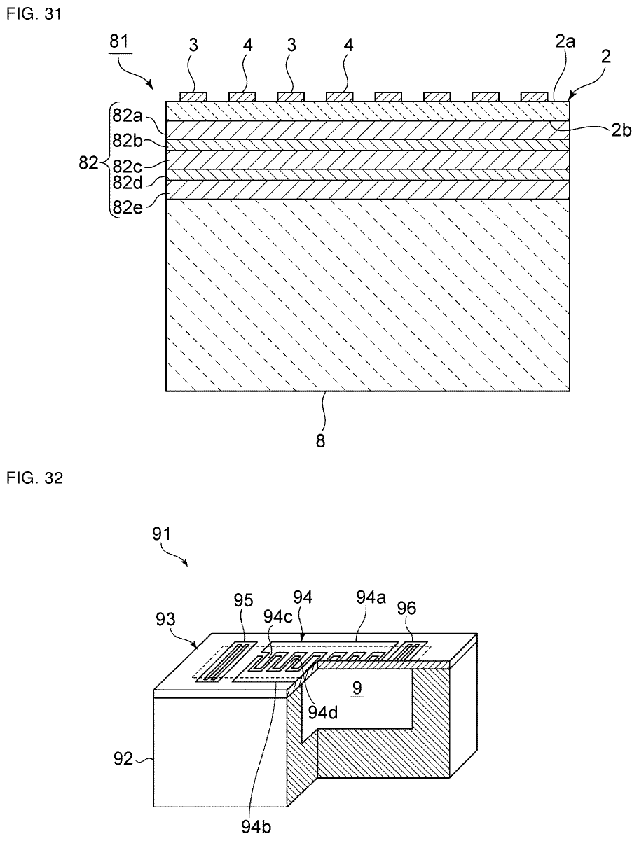

FIG. 31 is an elevational cross-sectional view of an acoustic wave device including an acoustic multilayer film.

In an acoustic wave device 81, an acoustic multilayer film 82 is laminated on the second main surface 2b of the piezoelectric layer 2. The acoustic multilayer film 82 includes a multilayer structure of low acoustic impedance layers 82a, 82c, and 82e having a relatively low acoustic impedance and high acoustic impedance layers 82b and 82d having a relatively high acoustic impedance. In a case where the acoustic multilayer film 82 is used, the bulk wave in the thickness shear mode can be confined in the piezoelectric layer 2 without using the cavity portion 9 in the acoustic wave device 1. In the acoustic wave device 81 as well, the resonance characteristics based on the bulk wave in the thickness shear mode can be obtained by setting d/p to about 0.5 or less, for example. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d may be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d described above can be made of appropriate material as long as the relationship of the acoustic impedance described above is satisfied. Examples of the materials of the low acoustic impedance layers 82a, 82c, and 82e include silicon oxide, silicon oxynitride, and the like. In addition, examples of the materials of the high acoustic impedance layers 82b and 82d include alumina, silicon nitride, metal, and the like.

FIG. 32 is a perspective view of a partial notch for describing an acoustic wave device using a Lamb wave.

An acoustic wave device 91 includes a support substrate 92. The support substrate 92 is provided with a recess portion that is open on an upper surface. A piezoelectric layer 93 is laminated on the support substrate 92. As a result, the cavity portion 9 is provided. An IDT electrode 94 is provided on the piezoelectric layer 93 above the cavity portion 9. Reflectors 95 and 96 are provided on both sides of the IDT electrode 94 in an acoustic wave propagation direction. In FIG. 32, an outer periphery of the cavity portion 9 is indicated by broken lines. Here, the IDT electrode 94 includes first and second busbars 94a and 94b, a plurality of first electrode fingers 94c, and a plurality of second electrode fingers 94d. The plurality of first electrode fingers 94c are connected to the first busbar 94a. The plurality of second electrode fingers 94d are connected to the second busbar 94b. The plurality of first electrode fingers 94c and the plurality of second electrode fingers 94d are interdigitated with each other.

In the acoustic wave device 91, the Lamb wave as the plate wave is excited by applying an alternating current electric field to the IDT electrodes 94 on the cavity portion 9. Since the reflectors 95 and 96 are provided on both sides, the resonance characteristics caused by the Lamb wave can be obtained.

In this manner, the acoustic wave resonator in the present invention may use a plate wave. In the example illustrated in FIG. 32, the IDT electrode 94, the reflector 95, and the reflector 96 are provided on a main surface corresponding to the first main surface 14a of the piezoelectric layer 14 illustrated in FIG. 1 and the like. On the other hand, in a first acoustic element according to an example embodiment of the present invention, one pair of comb-shaped electrodes and the plurality of third electrode fingers are provided on the first main surface 14a. In a case where the first acoustic element according to an example embodiment of the present invention uses the plate wave, the first main surface 14a of the piezoelectric layer 14 in the first to fifth example embodiments and each of the modification examples may be provided with one pair of comb-shaped electrodes, a plurality of third electrode fingers, and the reflector 95 and the reflector 96. In this case, the pair of comb-shaped electrodes and the plurality of third electrode fingers may be interposed between the reflector 95 and the reflector 96 in the electrode finger orthogonal direction.

In a case where a second acoustic element according to an example embodiment of the present invention is an acoustic wave resonator that includes an IDT electrode and uses a plate wave, for example, the following configuration may be adopted. That is, the IDT electrode, the reflector 95, and the reflector 96 need only be provided on the first main surface 14a of the piezoelectric layer 14 in the first example embodiment, the second example embodiment, the fourth example embodiment, and the modification example. In this case, the IDT electrode may be interposed between the reflector 95 and the reflector 96 in the electrode finger orthogonal direction.

Alternatively, in a case where a second acoustic element according to an example embodiment of the present invention is an acoustic coupling filter using a plate wave, the second acoustic element may have the same configuration as the first acoustic element. That is, it is sufficient that one pair of comb-shaped electrodes, the plurality of third electrode fingers, and the reflector 95 and the reflector 96 may be provided on the first main surface 14a of the piezoelectric layer 14 in the fifth example embodiment and each modification example of the fifth example embodiment. In this case, the one pair of comb-shaped electrodes and the plurality of third electrode fingers may be interposed between the reflector 95 and the reflector 96 in the electrode finger orthogonal direction.

In the acoustic wave device according to the first to fifth example embodiments and each of the modification examples, for example, the acoustic multilayer film 82 illustrated in FIG. 31 may be provided as an acoustic reflection film between a support and a piezoelectric layer as a piezoelectric film. Specifically, the support and the piezoelectric film may be disposed such that at least a portion of the support and at least a portion of the piezoelectric film face each other with the acoustic multilayer film 82 interposed therebetween. In this case, in the acoustic multilayer film 82, the low acoustic impedance layer and the high acoustic impedance layer may be alternately laminated. The acoustic multilayer film 82 may be the acoustic reflection portion in the acoustic wave device. Then, the plurality of electrode fingers of the first acoustic element and the plurality of electrode fingers of the second acoustic element may overlap with the same acoustic multilayer film 82 in plan view.

In a case where the acoustic reflection portion is the acoustic multilayer film 82, it is preferable that at least one of the low acoustic impedance layer and the high acoustic impedance layer is a dielectric layer. As a result, a parasitic capacitance can be reduced.

In the first to fifth example embodiments and each modification example in which the bulk wave in the thickness shear mode is used, d/p is preferably about 0.5 or less and more preferably about 0.24 or less, for example, as described above in the first acoustic element. As a result, better resonance characteristics can be obtained. The same applies to the second acoustic element in the first example embodiment, the second example embodiment, the fourth example embodiment, the fifth example embodiment, and each modification example, in which the bulk wave in the thickness shear mode is used.

Further, in the excitation region of the first acoustic element in the first to fifth example embodiments and each modification example using the bulk wave in the thickness shear mode, it is preferable that MR≤about 1.75 (d/p)+0.075 is satisfied, for example, as described above. More specifically, it is preferable that, in a case where a metallization ratio of the first electrode finger and the third electrode finger, and the second electrode finger and the third electrode finger, with respect to the excitation region is defined as MR, MR≤about 1.75 (d/p)+0.075 is satisfied. In this case, it is possible to more reliably suppress the spurious. The same applies to the excitation region of the second acoustic element in the first example embodiment, the second example embodiment, the fourth example embodiment, the fifth example embodiment, and each modification example, in which the bulk wave in the thickness shear mode is used.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a plurality of acoustic elements; wherein
the plurality of acoustic elements share a support, and a piezoelectric film that is provided on the support and includes a piezoelectric layer including a piezoelectric body;
the plurality of acoustic elements include a first acoustic element and a second acoustic element that is electrically connected to the first acoustic element, and the first acoustic element is an acoustic coupling filter;
the first acoustic element includes:
a first comb-shaped electrode that is provided on the piezoelectric layer, includes a first busbar and a plurality of first electrode fingers each including one end connected to the first busbar, and is connected to an input potential;
a second comb-shaped electrode that is provided on the piezoelectric layer, includes a second busbar and a plurality of second electrode fingers each including one end connected to the second busbar and interdigitated with the plurality of first electrode fingers, and is connected to an output potential; and
a third electrode that includes a plurality of third electrode fingers which are provided on the piezoelectric layer side by side with the first electrode fingers and the second electrode fingers in a direction in which the first electrode fingers and the second electrode fingers are arranged side by side when viewed in plan view and a connection electrode which connects the third electrode fingers adjacent to each other, the third electrode being connected to a potential different from the input potential to which the first comb-shaped electrode is connected and the output potential to which the second comb-shaped electrode is connected;
an order in which a first electrode finger among the first electrode fingers, a second electrode finger among the second electrode fingers, and a third electrode finger among the third electrode fingers are arranged side by side is an order in which the first electrode finger, the third electrode finger, the second electrode finger, and the third electrode finger define one period in a case where the order is started from the first electrode finger;
the second acoustic element includes a functional electrode that is provided on the piezoelectric layer; and
an acoustic reflection portion is provided at a position in the support overlapping with the plurality of first electrode fingers, the plurality of second electrode fingers, and the plurality of third electrode fingers of the first acoustic element and the functional electrode of the second acoustic element in plan view.

2. The acoustic wave device according to claim 1, wherein the first acoustic element is structured to generate a bulk wave in a thickness shear mode.

3. The acoustic wave device according to claim 1, wherein in a case where a longest distance among a center-to-center distance between the first electrode finger and the third electrode finger adjacent to each other and a center-to-center distance between the second electrode finger and the third electrode finger adjacent to each other in the first acoustic element is denoted by p and a thickness of the piezoelectric film is denoted by d, d/p is about 0.5 or less.

4. The acoustic wave device according to claim 3, wherein d/p is about 0.24 or less.

5. The acoustic wave device according to claim 3,
wherein when a direction orthogonal to a direction in which the first electrode finger, the second electrode finger, and the third electrode finger extend is defined as an electrode finger orthogonal direction, in the first acoustic element, a region in which the first electrode finger and the third electrode finger adjacent to each other overlap with each other in the electrode finger orthogonal direction and which is a region between centers of the first electrode finger and the third electrode finger adjacent to each other, and a region in which the second electrode finger and the third electrode finger adjacent to each other overlap with each other in the electrode finger orthogonal direction and which is a region between centers of the second electrode finger and the third electrode finger adjacent to each other are an excitation region; and
when a metallization ratio of the first electrode finger and the third electrode finger, and the second electrode finger and the third electrode finger, with respect to the excitation region is defined as MR, MR≤about 1.75 (d/p)+0.075 is satisfied.

6. The acoustic wave device according to claim 1, wherein
the second acoustic element is an acoustic coupling filter;
the second acoustic element includes a first comb-shaped electrode, a second comb-shaped electrode, and a reference potential electrode, which are independent from the first acoustic element, the first comb-shaped electrode of the second acoustic element includes a first busbar and a plurality of first electrode fingers, and is connected to an input potential, the second comb-shaped electrode of the second acoustic element includes a second busbar and a plurality of second electrode fingers, and is connected to an output potential, and the reference potential electrode of the second acoustic element includes a plurality of third electrode fingers and a connection electrode, and is connected to a reference potential; and
at least one of a total number of first electrode fingers, second electrode fingers, and third electrode fingers, a center-to-center distance between the first electrode finger and the third electrode finger adjacent to each other and a center-to-center distance between the second electrode finger and the third electrode finger adjacent to each other, a width of the first electrode finger, the second electrode finger, and the third electrode finger, and a thickness of the first electrode finger, the second electrode finger, and the third electrode finger is different between the first acoustic element and the second acoustic element.

7. The acoustic wave device according to claim 1, wherein
the second acoustic element is an acoustic coupling filter;
the second acoustic element includes a first comb-shaped electrode, a second comb-shaped electrode, and a reference potential electrode, which are independent from the first acoustic element, the first comb-shaped electrode of the second acoustic element includes a first busbar and a plurality of first electrode fingers, and is connected to an input potential, the second comb-shaped electrode of the second acoustic element includes a second busbar and a plurality of second electrode fingers, and is connected to an output potential, and the reference potential electrode of the second acoustic element includes a plurality of third electrode fingers and a connection electrode, and is connected to a reference potential;
in each of the first acoustic element and the second acoustic element, a tip of each of the plurality of first electrode fingers and the plurality of second electrode fingers faces an electrode connected to a potential which is different from a potential to which the electrode finger is connected and is any of the input potential, the output potential, and the reference potential with a gap therebetween; and
in each of the first acoustic element and the second acoustic element, when a direction in which the first electrode finger, the second electrode finger, and the third electrode finger extend is defined as an electrode finger extending direction and a dimension of the gap in the electrode finger extending direction is defined as a gap length, the gap length is different between the first acoustic element and the second acoustic element.

8. The acoustic wave device according to claim 1, wherein
the second acoustic element is an acoustic coupling filter;
the second acoustic element includes a first comb-shaped electrode, a second comb-shaped electrode, and a reference potential electrode, which are independent from the first acoustic element, the first comb-shaped electrode of the second acoustic element includes a first busbar and a plurality of first electrode fingers, and is connected to an input potential, the second comb-shaped electrode of the second acoustic element includes a second busbar and a plurality of second electrode fingers, and is connected to an output potential, and the reference potential electrode of the second acoustic element includes a plurality of third electrode fingers and a connection electrode, and is connected to a reference potential;
in each of the first acoustic element and the second acoustic element, when a direction in which the first electrode finger, the second electrode finger, and the third electrode finger extend is defined as an electrode finger extending direction, a region in which the first electrode finger and the second electrode finger overlap with each other when viewed from a direction orthogonal to the electrode finger extending direction is an intersecting region; and
in each of the first acoustic element and the second acoustic element, when a dimension of the intersecting region in the electrode finger extending direction is defined as an intersecting width, the intersecting width is different between the first acoustic element and the second acoustic element.

9. The acoustic wave device according to claim 1, wherein
the second acoustic element is an acoustic wave resonator other than the acoustic coupling filter; and
the functional electrode of the second acoustic element is an IDT electrode.

10. The acoustic wave device according to claim 6, wherein the second acoustic element is structured to generate a plate wave.

11. The acoustic wave device according to claim 6, wherein the second acoustic element is structured to generate a bulk wave in a thickness shear mode.

12. The acoustic wave device according to claim 1, wherein
the second acoustic element is a capacitive element; and
the functional electrode of the capacitive element is an IDT electrode.

13. The acoustic wave device according to claim 1, wherein
the second acoustic element is a bulk wave resonator;
the piezoelectric film is the piezoelectric layer, and the piezoelectric layer includes a first main surface and a second main surface facing each other;
the functional electrode of the second acoustic element includes a fourth electrode provided on the first main surface and a fifth electrode provided on the second main surface; and
the fourth electrode and the fifth electrode face each other with the piezoelectric layer interposed therebetween.

14. The acoustic wave device according to claim 1, wherein the acoustic reflection portion includes a cavity portion, and the support and the piezoelectric film are positioned such that a portion of the support and a portion of the piezoelectric film face each other with the cavity portion interposed therebetween.

15. The acoustic wave device according to claim 1, wherein the acoustic reflection portion is an acoustic reflection film including a high acoustic impedance layer having a relatively high acoustic impedance and a low acoustic impedance layer having a relatively low acoustic impedance, and the support and the piezoelectric film are positioned such that at least a portion of the support and at least a portion of the piezoelectric film face each other with the acoustic reflection film interposed therebetween.

16. The acoustic wave device according to claim 15, wherein at least one of the low acoustic impedance layer and the high acoustic impedance layer is a dielectric layer.

17. The acoustic wave device according to claim 1, wherein
the piezoelectric layer is made of lithium niobate; and
Euler angles (φ, θ, ψ) of the lithium niobate of the piezoelectric layer are in a range of Formula (1), Formula (2), or Formula (3):
(Within a range of 0°±10°, 0° to 25°, any ψ) Formula (1);
(Within a range of 0°±10°, 25° to 100°, 0° to 75° [(1−(0−50)²/2500)]^{1/2} or 180°−75°[(1−(θ−50)²/2500)]^{1/2} to 180°) Formula (2);
(Within a range of 0°±10°, 180°−40°[(1−(ψ−90)²/8100)]^{1/2} to 180°, any ψ) Formula (3).
